(19) United States
(12) Patent Application Publication
(10) Pub. No.: US 2022/0077256 A1
(43) Pub. Date: Mar. 10, 2022

(54) DISPLAY DEVICE

(71) Applicant: SAMSUNG DISPLAY CO., LTD., YONGIN-SI, GYEONGGI-DO (KR)

(72) Inventors: Jae Ik LIM, HWASEONG-DI, GYEONGGI-DO (KR); Gee Bum KIM, SEOUL (KR); Jung Ha SON, YONGIN-SI, GYEONGGI-DO (KR)

(21) Appl. No.: 17/421,196

(22) PCT Filed: Nov. 21, 2019
(86) PCT No.: PCT/KR2019/016053

§ 371 Date: Jul. 7, 2021

(30) Foreign Application Priority Data
Jan. 7, 2019 (KR) 10-2019-0001721

(51) Int. Cl. H01L 27/32; H01L 51/52; G06F 3/044

(52) U.S. Cl. CPC H01L 27/3246; H01L 51/5271; H01L 51/5237; G06F 3/0446; H01L 27/323; H01L 27/3211; H01L 51/5275

(57) ABSTRACT

A display device includes a subpixel which including a first electrode, a light emitting layer, and a second electrode. The display device further includes a pixel defining layer defining the subpixel, a first total reflection layer overlapping the pixel defining layer, a second total reflection layer disposed on the first total reflection layer, and a planarization layer disposed on the second total reflection layer. A refractive index of the planarization layer is greater than a refractive index of the second total reflection layer, and the refractive index of the second total reflection layer is greater than a refractive index of the first total reflection layer.

### CROSS-REFERENCE TO RELATED APPLICATIONS

The present application is a National Stage application, filed under 35 U.S.C. § 371, of International Patent Application No. PCT/KR2019/016053, filed on Nov. 21, 2019, which claims priority to Korean Patent Application No. KR 10-2019-0001721, filed on Jan. 7, 2019, the contents of which are incorporated by reference herein in their entirety.

### TECHNICAL FIELD

The present disclosure relates to a display device.

### DISCUSSION OF RELATED ART

As technological advances are made, the demand for display devices for displaying images is increasing. Accordingly, various display devices such as liquid crystal displays, plasma display panels, and organic light emitting displays are being utilized.

Among the display devices, organic light emitting displays, which are self-light emitting display devices, have an increased viewing angle and contrast ratio compared to liquid crystal displays. Since the organic light emitting displays do not require a separate backlight, they can be made lightweight and thin, and are advantageous with regard to power consumption. In addition, the organic light emitting displays can be driven with a direct current low voltage and have advantages of fast response speed and, in particular, low manufacturing cost.

An organic light emitting display includes an organic light emitting element which emits light and a pixel defining layer which defines the organic light emitting element. The organic light emitting element includes an anode, a hole transporting layer, an organic light emitting layer, an electron transporting layer, and a cathode. In this case, when a high potential voltage is applied to the anode, and a low potential voltage is applied to the cathode, holes and electrons move to the organic light emitting layer respectively through the hole transporting layer and the electron transporting layer and combine together in the organic light emitting layer to emit light.

A part of light emitted from the organic light emitting element may travel in a lateral direction rather than an upward direction of the organic light emitting display. In this case, the part of the light can be lost without being output in the upward direction of the organic light emitting display. Increasing the output efficiency of light emitted from the organic light emitting element cannot only increase the life of the organic light emitting element, but also, can reduce the power consumption of the organic light emitting display.

### SUMMARY

In an embodiment, a display device includes a subpixel including a first electrode, a light emitting layer, and a second electrode. The display device further includes a pixel defining layer defining the subpixel, a first total reflection layer overlapping the pixel defining layer, a second total reflection layer disposed on the first total reflection layer, and a planarization layer disposed on the second total reflection layer. A refractive index of the planarization layer is greater than a refractive index of the second total reflection layer, and the refractive index of the second total reflection layer is greater than a refractive index of the first total reflection layer.

In an embodiment, a maximum thickness of the planarization layer is greater than a maximum thickness of the first total reflection layer, and the maximum thickness of the first total reflection layer is greater than a maximum thickness of the second total reflection layer.

In an embodiment, the first total reflection layer does not overlap the subpixel.

In an embodiment, the display device further includes an encapsulation layer disposed on the second electrode of the subpixel and the pixel defining layer. The first total reflection layer is disposed on the encapsulation layer, and the second total reflection layer is disposed on a portion of the encapsulation layer that is not covered by the first total reflection layer.

In an embodiment, the display device further includes a buffer layer disposed between the encapsulation layer and the first total reflection layer.

In an embodiment, the first total reflection layer surrounds the subpixel in a plan view.

In an embodiment, the display device further includes a touch electrode overlapping the pixel defining layer.

In an embodiment, the touch electrode does not overlap the first total reflection layer.

In an embodiment, the second total reflection layer covers the touch electrode.

In an embodiment, the first total reflection layer covers the touch electrode.

In an embodiment, the first total reflection layer includes an opening area exposing the subpixel in a plan view.

In an embodiment, the display device further includes a touch insulating layer covering the touch electrode. The first total reflection layer is disposed on the touch insulating layer.

In an embodiment, the display device further includes a third total reflection layer overlapping the pixel defining layer. The first total reflection layer surrounds the subpixel in a plan view, and the third total reflection layer surrounds the first total reflection layer in the plan view.

In an embodiment, the display device further includes a fourth total reflection layer disposed on the third total reflection layer. A refractive index of the fourth total reflection layer is greater than a refractive index of the third total reflection layer.

In an embodiment, the display device further includes an encapsulation layer disposed on the second electrode of the subpixel and the pixel defining layer. The first total reflection layer and the third total reflection layer are disposed on the encapsulation layer, and the second total reflection layer is disposed on the third total reflection layer and a portion of the encapsulation layer that is not covered by the first total reflection layer and the third total reflection layer.

In an embodiment, the display device further includes a touch electrode overlapping the pixel defining layer.

In an embodiment, the touch electrode does not overlap the first total reflection layer and the third total reflection layer.

In an embodiment, the second total reflection layer covers the touch electrode.

In an embodiment, the third total reflection layer covers the touch electrode.

In an embodiment, the display device further includes a touch insulating layer covering the touch electrode. The first total reflection layer and the third total reflection layer are disposed on the touch insulating layer.

In an embodiment, the first total reflection layer includes a first inclined surface adjacent to the subpixel, and the second total reflection layer comprises a second inclined surface disposed on the first inclined surface. An inclination angle of the first inclined surface is defined as a first taper angle, an inclination angle of the second inclined surface is defined as a second taper angle, and each of the first taper angle and the second taper angle increases as each of an output angle of light that is totally reflected by the first total reflection layer and an output angle of light that is totally reflected by the second total reflection layer increases.

In an embodiment, the first total reflection layer includes a first inclined surface adjacent to the subpixel, and the second total reflection layer includes a second inclined surface disposed on the first inclined surface. An inclination angle of the first inclined surface is defined as a first taper angle, an inclination angle of the second inclined surface is defined as a second taper angle, and each of the first taper angle and the second taper angle decreases as an output angle of light that is refracted by the second total reflection layer and then totally reflected by the first total reflection layer increases.

In a display device according to an embodiment, light travelling in a lateral direction rather than an upward direction among light of subpixels may be totally reflected from a third inclined surface of a second total reflection layer, may be totally reflected from a first inclined surface of a first total reflection layer, or may be refracted from the third inclined surface of the second total reflection layer and then totally reflected from the first inclined surface of the first total reflection layer to travel in the upward direction. Therefore, it is possible to increase the light output efficiency of the subpixels, thereby increasing the life of organic light emitting elements and reducing the power consumption of the organic light emitting display.

Aspects of the present disclosure provide a display device which can increase light output efficiency.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other features of the present invention will become more apparent by describing in detail embodiments thereof with reference to the accompanying drawings, in which:

FIG. 1 is a perspective view of a display device according to an embodiment;

FIG. 2 is a plan view of the display device according to an embodiment;

FIG. 3 is a cross-sectional view illustrating an example taken along line I-I′ of FIG. 2;

FIG. 4 is an exemplary view illustrating an example of a display unit of FIG. 3 in detail;

FIG. 5 is an exemplary view illustrating an example of a touch sensing unit of FIG. 3 in detail;

FIG. 6 is a plan view illustrating an example of area A of FIG. 5, specifically, an example of subpixels of FIG. 4 and a driving electrode of FIG. 5;

FIG. 7 is a cross-sectional view illustrating an example taken along line II-II′ of FIG. 6;

FIG. 8 is a cross-sectional view illustrating another example taken along line 11-II′ of FIG. 6;

FIG. 9 is a cross-sectional view illustrating an example of area B of FIG. 7 in detail;

FIG. 10 is a graph illustrating a second taper angle of a second total reflection layer with respect to an output angle for each refractive index of a high refractive planarization layer for outputting second light;

FIG. 11 is a graph illustrating a minimum angle of the second taper angle of the second total reflection layer with respect to the refractive index of the high refractive planarization layer for each refractive index of the second total reflection layer for outputting the second light;

FIG. 12 is a graph illustrating an example of a first taper angle of a first total reflection layer with respect to an output angle for each second taper angle of the second total reflection layer for outputting third light;

FIG. 13 is a graph illustrating another example of the first taper angle of the first total reflection layer with respect to the output angle for each second taper angle of the second total reflection layer for outputting the third light;

FIG. 14 is a cross-sectional view illustrating another example of area B of FIG. 7 in detail;

FIG. 15 is a cross-sectional view illustrating another example of area B of FIG. 7 in detail;

FIG. 16 is a plan view illustrating another example of area A of FIG. 5, specifically, another example of the subpixels of FIG. 4 and a first touch metal layer of FIG. 5;

FIG. 17 is a cross-sectional view illustrating an example taken along line III-III′ of FIG. 16;

FIG. 18 is a cross-sectional view illustrating another example taken along line III-III′ of FIG. 16;

FIG. 19 is a plan view illustrating another example of area A of FIG. 5, specifically, another example of the subpixels of FIG. 4 and the first touch metal layer of FIG. 5;

FIG. 20 is a cross-sectional view illustrating an example taken along line IV-IV′of FIG. 19;

FIG. 21 is a plan view illustrating another example of area A of FIG. 5, specifically, another example of the subpixels of FIG. 4 and the first touch metal layer of FIG. 5;

FIG. 22 is a cross-sectional view illustrating an example taken along line V-V′ of FIG. 21; and

FIG. 23 is a cross-sectional view illustrating another example taken along line V-V′ of FIG. 21.

### DETAILED DESCRIPTION OF THE EMBODIMENTS

Embodiments of the present invention will be described more fully hereinafter with reference to the accompanying drawings.

When an element or layer is referred to as being “on” another element or layer, it includes all cases in which another layer or another element is interposed directly on or in the middle of another element. The same reference numerals refer to the same elements throughout the specification. The shapes, sizes, ratios, angles, numbers, etc. disclosed in the drawings for describing the embodiments are exemplary, and the present invention is not limited to the illustrated matters.

Although the terms “first”, “second”, and the like are used to describe various components, these components are not limited by these terms. These terms are only used to distinguish one component from another component. Therefore, a first component mentioned below may also be referred to as a second component within the technical idea of the present invention.

Each of the features of the various embodiments of the present invention can be partially or entirely combined with each other.

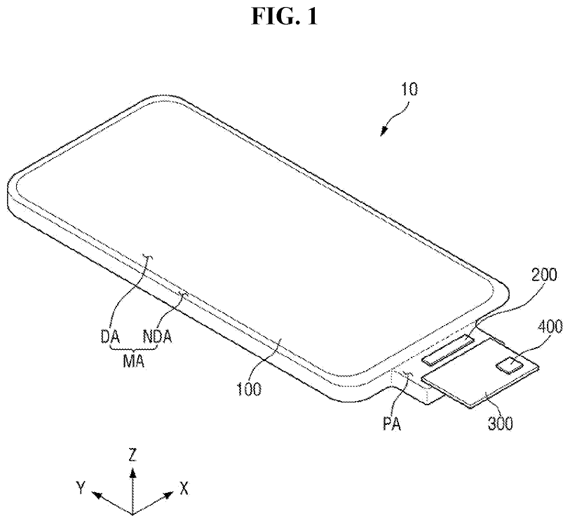

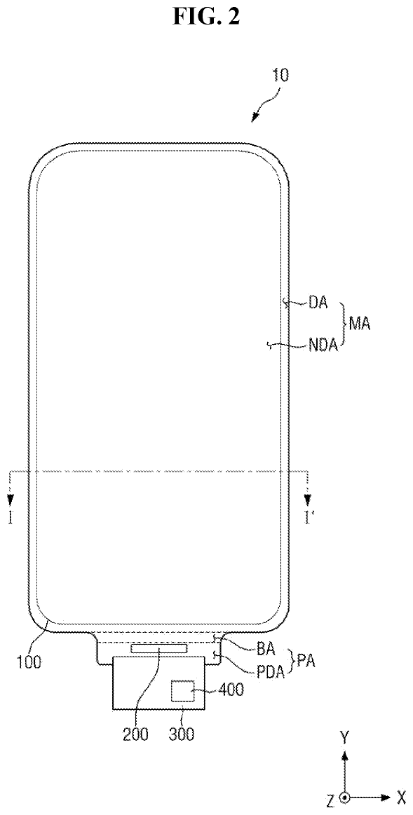

FIG. 1 is a perspective view of a display device according to an embodiment. FIG. 2 is a plan view of the display device according to the embodiment.

In the present specification, the terms “above,” “top,” and “upper surface” refer to an upward direction from a display panel 100, that is, a Z-axis direction, and the terms “under,” “bottom,” and “lower surface” refer to a downward direction from the display panel 100, that is, a direction opposite to the Z-axis direction. In addition, the terms “left,” “right,” “upper,” and “lower” refer to directions when the display panel 100 is seen on a plane. For example, the term “left” refers to a direction opposite to an X-axis direction, the term “right” refers to the X-axis direction, the term “upper” refers to a Y-axis direction, and the term “lower” refers to a direction opposite to the Y-axis direction.

Referring to FIGS. 1 and 2, the display device 10 is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and the Internet of Things (IoT) devices. The display device 10 may be any one of an organic light emitting display, a liquid crystal display, a plasma display panel, a field emission display, an electrophoretic display, an electrowetting display, a quantum dot light emitting display, and a micro light emitting diode (LED) display. A case in which the display device 10 is an organic light emitting display will be mainly described below, but the present disclosure is not limited thereto.

The display device 10 according to an embodiment includes the display panel 100, a display driving circuit 200, a circuit board 300, and a touch driving circuit 400.

The display panel 100 may include a main area MA and a protruding area PA protruding from a side of the main area MA.

The main area MA may be formed as a rectangular plane having short sides in a first direction (X-axis direction) and long sides in a second direction (Y-axis direction) intersecting the first direction (X-axis direction). Each corner where a short side extending in the first direction (X-axis direction) meets a long side extending in the second direction (Y-axis direction) may be rounded with a predetermined curvature or may be right-angled. The planar shape of the display device 10 is not limited to a quadrangular shape, but may also be other polygonal shapes such as a circular shape, or an elliptical shape. The main area MA may be formed flat. However, embodiments of the present disclosure are not limited thereto, and the main area MA may also include curved parts formed at its left and right ends. In this case, the curved parts may have a constant curvature or a varying curvature.

The main area MA may include a display area DA where pixels are formed to display an image and a non-display area NDA disposed around the display area DA.

In the display area DA, not only the pixels, but also scan lines, data lines and a power line connected to the pixels may be disposed. When the main area MA includes a curved part, the display area DA may be disposed in the curved part. In this case, an image of the display panel 100 may also be seen in the curved part.

The non-display area NDA may be defined as an area extending from the outside of the display area DA to edges of the display panel 100. A scan driver for transmitting scan signals to the scan lines and link lines connecting the data lines and the display driving circuit 200 may be disposed in the non-display area NDA.

The protruding area PA may protrude from a side of the main area MA. For example, the protruding area PA may protrude from a lower side of the main area MA as illustrated in FIG. 2. A length of the protruding area PA in the first direction (X-axis direction) may be smaller than a length of the main area MA in the first direction (X-axis direction).

The protruding area PA may include a bending area BA and a pad area PDA. In this case, the pad area PDA may be disposed on a side of the bending area BA, and the main area MA may be disposed on the other side of the bending area BA. For example, the pad area PDA may be disposed on a lower side of the bending area BA, and the main area MA may be disposed on an upper side of the bending area BA.

The display panel 100 may be formed to be flexible so that it can be curved, bent, folded, or rolled. Therefore, the display panel 100 may be bent in the bending area BA in a thickness direction (Z-axis direction). In this case, while a surface of the pad area PDA of the display panel 100 faces upward before the display panel 100 is bent, the surface of the pad area PDA of the display panel 100 faces downward after the display panel 100 is bent. Accordingly, since the pad area PDA is disposed under the main area MA, it may be overlapped by the main area MA.

Pads electrically connected to the display driving circuit 200 and the circuit board 300 may be disposed on the pad area PDA of the display panel 100.

The display driving circuit 200 outputs signals and voltages for driving the display panel 100. For example, the display driving circuit 200 may supply data voltages to the data lines. In addition, the display driving circuit 200 may supply a power supply voltage to the power line and supply scan control signals to the scan driver. The display driving circuit 200 may be formed as an integrated circuit and mounted on the display panel 100 in the pad area PDA using a chip on glass (COG) method, a chip on plastic (COP) method, or an ultrasonic bonding method. However, embodiments of the present disclosure are not limited thereto. For example, the display driving circuit 200 may be mounted on the circuit board 300.

The pads may include display pads electrically connected to the display driving circuit 200 and touch pads electrically connected to touch lines.

The circuit board 300 may be attached onto the pads using an anisotropic conductive film. Therefore, lead lines of the circuit board 300 may be electrically connected to the pads. The circuit board 300 may be a flexible printed circuit board, a printed circuit board, or a flexible film such as a chip-on-film.

The touch driving circuit 400 may be connected to touch electrodes of a touch sensor layer TSL of the display panel 100. The touch driving circuit 400 transmits driving signals to the touch electrodes of the touch sensor layer TSL and measures capacitance values of the touch electrodes. Each of the driving signals may be a signal having a plurality of driving pulses. The touch driving circuit 400 may not only determine whether a touch has been input, but may also calculate touch coordinates at which the touch has been input based on the capacitance values.

The touch driving circuit 400 may be disposed on the circuit board 300. The touch driving circuit 400 may be formed as an integrated circuit and mounted on the circuit board 300.

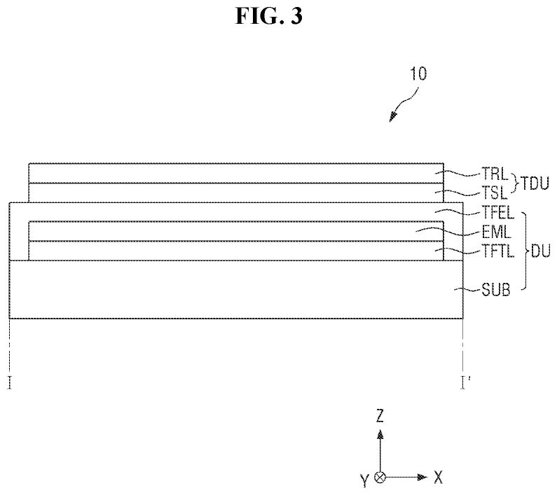

FIG. 3 is a cross-sectional view illustrating an example take along line I-I′ of FIG. 2.

Referring to FIG. 3, the display panel 100 may include a display unit DU having a substrate SUB, a thin-film transistor layer TFTL disposed on the substrate SUB, a light emitting element layer EML, and a thin-film encapsulation layer TFEL, and may also include a touch sensing unit TDU having the touch sensor layer TSL and a total reflection layer TRL.

The substrate SUB may be made of an insulating material such as glass, quartz, or polymer resin. The polymer material may be, for example, polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (Pl), polycarbonate (PC), cellulose triacetate (CAT), cellulose acetate propionate (CAP), or a combination thereof. Alternatively, the substrate SUB may include a metal material.

The substrate SUB may be a rigid substrate or a flexible substrate that can be bent, folded, or rolled. When the substrate SUB is a flexible substrate, it may be made of, but not limited to, polyimide (PI).

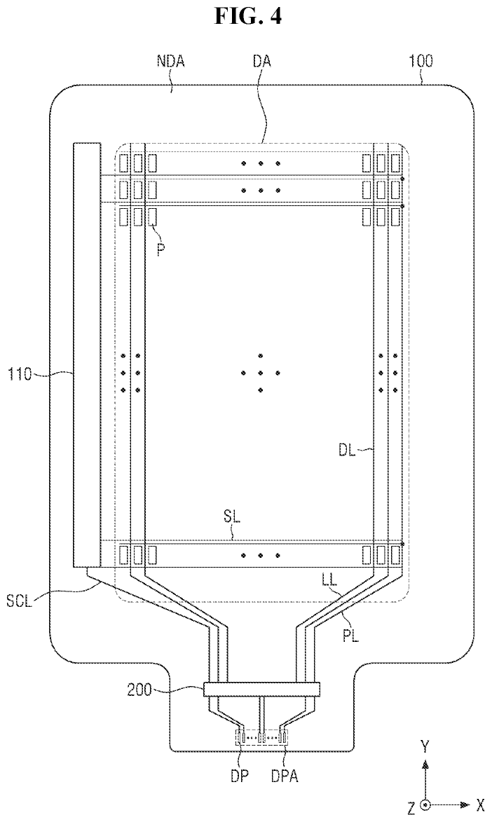

The thin-film transistor layer TFTL may be disposed on the substrate SUB. In the thin-film transistor layer TFTL, not only respective thin-film transistors of pixels, but also scan lines, data lines, power lines, scan control lines, and routing lines connecting pads and the data lines may be formed. Each of the thin-film transistors may include a gate electrode, a semiconductor layer, a source electrode, and a drain electrode. When a scan driver 110 is formed in the non-display area NDA of the display panel 100 as illustrated in FIG. 4, it may include thin-film transistors.

The thin-film transistor layer TFTL may be disposed in the display area DA and the non-display area NDA. Specifically, the respective thin-film transistors of the pixels, the scan lines, the data lines, and the power lines of the thin-film transistor layer TFTL may be disposed in the display area DA. The scan control lines and the link lines of the thin-film transistor layer TFTL may be disposed in the non-display area NDA.

The light emitting element layer EML may be disposed on the thin-film transistor layer TFTL. The light emitting element layer EML may include the pixels, each including a first electrode, a light emitting layer and a second electrode, and a pixel defining layer defining the pixels. The light emitting layer may be an organic light emitting layer including an organic material. In this case, the light emitting layer may include a hole transporting layer, an organic light emitting layer, and an electron transporting layer. When a predetermined voltage is applied to the first electrode through a thin-film transistor of the thin-film transistor layer TFTL, and a cathode voltage is applied to the second electrode, holes and electrons move to the organic light emitting layer respectively through the hole transporting layer and the electron transporting layer and combine together in the organic light emitting layer to emit light. The pixels of the light emitting element layer EML may be disposed in the display area DA.

The thin-film encapsulation layer TFEL may be disposed on the light emitting element layer EML. The thin-film encapsulation layer TFEL prevents oxygen or moisture from penetrating into the light emitting element layer EML. To this end, the thin-film encapsulation layer TFEL may include at least one inorganic layer. The inorganic layer may be, but is not limited to, a silicon nitride layer, a silicon oxynitride layer, a silicon oxide layer, a titanium oxide layer, or an aluminum oxide layer. In addition, the thin-film encapsulation layer TFEL protects the light emitting element layer EML from foreign substances such as dust. To this end, the thin-film encapsulation layer TFEL may include at least one organic layer. The organic layer may be, but is not limited to, acryl resin, epoxy resin, phenolic resin, polyamide resin, or polyimide resin.

The thin-film encapsulation layer TFEL may be disposed in both the display area DA and the non-display area NDA. Specifically, the thin-film encapsulation layer TFEL may cover the light emitting element layer EML of the display area DA and the non-display area NDA and cover the thin-film transistor layer TFTL of the non-display area NDA.

The touch sensor layer TSL may be disposed on the thin-film encapsulation layer TFEL. Since the touch sensor layer TSL is disposed directly on the thin-film encapsulation layer TFEL, a thickness of the display device 10 can be reduced as compared with when a separate touch panel including the touch sensor layer TSL is attached onto the thin-film encapsulation layer TFEL.

The touch sensor layer TSL may include the touch electrodes for sensing a user's touch in a capacitive manner and the touch lines connecting the pads and the touch electrodes. For example, the touch sensor layer TSL may sense a user's touch in a self-capacitance manner or a mutual capacitance manner.

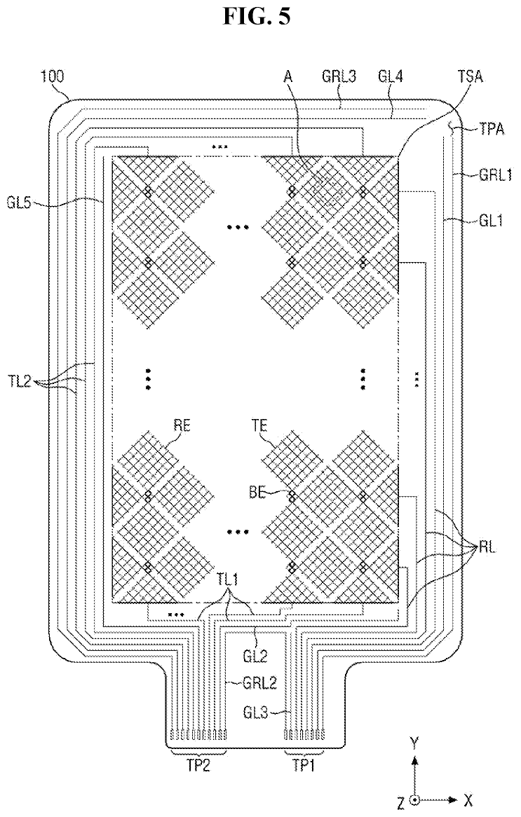

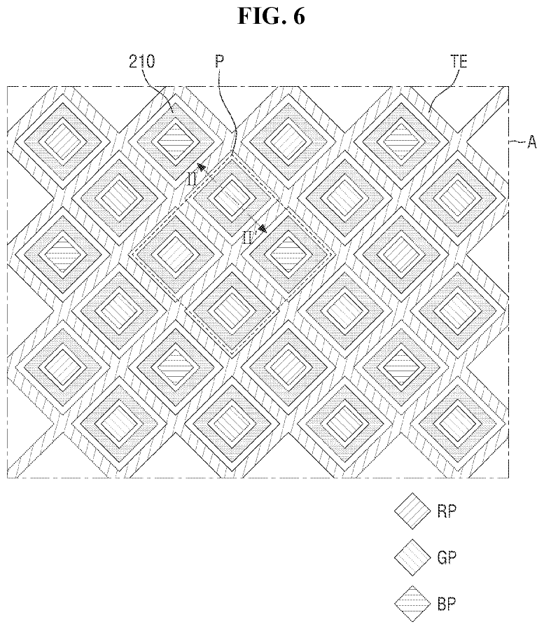

The touch electrodes of the touch sensor layer TSL may be disposed in a touch sensor area TSA overlapping the display area DA as illustrated in FIG. 5. The touch lines of the touch sensor layer TSL may be disposed in a touch peripheral area TPA overlapping the non-display area NDA as illustrated in FIG. 5.

The total reflection layer TRL may be disposed on the touch sensor layer TSL. The total reflection layer TRL is a layer that totally reflects light travelling in a lateral direction rather than the upward direction (Z-axis direction) of the display panel 100 among light of the light emitting element layer EML, so that the light can travel in the upward direction (Z-axis direction) of the display panel 100. Although the total reflection layer TRL is formed as a separate layer on the touch sensor layer TSL in FIG. 3, embodiments of the present disclosure are not limited thereto. For example, the touch sensor layer TSL and the total reflection layer TRL may be formed as one layer.

A cover window may be additionally disposed on the total reflection layer TRL. In this case, the total reflection layer TRL and the cover window may be bonded together by a transparent adhesive member such as an optically clear adhesive (OCA) film.

FIG. 4 is an exemplary view illustrating an example of the display unit of FIG. 3 in detail.

In FIG. 4, only pixels P, scan lines SL, data lines DL, a power line PL, scan control lines SCL, the scan driver 110, the display driving circuit 200, and display pads DP of the display unit DU are illustrated for ease of description.

Referring to FIG. 4, the scan lines SL, the data lines DL, the power line PL, and the pixels P are disposed in the display area DA. The scan lines SL may be formed parallel to each other in the first direction (X-axis direction), and the data lines DL may be formed parallel to each other in the second direction (Y-axis direction) intersecting the first direction (X-axis direction). The power line PL may include at least one line formed parallel to the data lines DL in the second direction (Y-axis direction) and a plurality of lines branching from the at least one line in the first direction (X-axis direction).

Each of the pixels P may be connected to at least any one of the scan lines SL, any one of the data lines DL, and the power line PL. Each of the pixels P may include thin-film transistors including a driving transistor and at least one switching transistor, an organic light emitting diode, and a capacitor. Each of the pixels P may receive a data voltage of a data line DL when a scan signal is transmitted from a scan line SL and may supply a driving current to the organic light emitting diode according to the data voltage applied to a gate electrode, thereby emitting light.

The scan driver 110 is connected to the display driving circuit 200 through at least one scan control line SCL. Therefore, the scan driver 110 may receive a scan control signal of the display driving circuit 200. The scan driver 110 generates scan signals according to the scan control signal and supplies the scan signals to the scan lines SL.

Although the scan driver 110 is formed in the non-display area NDA outside a left side of the display area DA in FIG. 5, embodiments of the present disclosure are not limited thereto. For example, the scan driver 110 may be formed in the non-display area NDA outside the left side and right side of the display area DA.

The display driving circuit 200 is connected to the display pads DP to receive digital video data and timing signals. The display driving circuit 200 converts the digital video data into analog positive/negative data voltages and supplies the data voltages to the data lines DL through link lines LL. In addition, the display driving circuit 200 generates a scan control signal for controlling the scan driver 110 and supplies the generated scan control signal to the scan driver 110 through the scan control lines SCL. Pixels P to be supplied with the data voltages are selected by the scan signals of the scan driver 110, and the data voltages are supplied to the selected pixels P. The display driving circuit 200 may be formed as an integrated circuit and attached onto the substrate SUB using a COG method, a COP method, or an ultrasonic bonding method.

FIG. 5 is an exemplary view illustrating an example of the touch sensing unit of FIG. 3 in detail.

In FIG. 5, only touch electrodes TE and RE, touch lines TL and RL, and touch pads TP are illustrated for ease of description.

Referring to FIG. 5, the touch sensing unit TDU includes the touch sensor area TSA for sensing a user's touch and the touch peripheral area TPA disposed around the touch sensor area TSA. The touch sensor area TSA may overlap the display area DA of the display unit DU, and the touch peripheral area TPA may overlap the non-display area NDA of the display unit DU.

The touch electrodes TE and RE may be disposed in the touch sensor area TSA. The touch electrodes TE and RE may include sensing electrodes RE electrically connected in the first direction (X-axis direction) and driving electrodes TE electrically connected in the second direction (Y-axis direction) intersecting the first direction (X-axis direction). In addition, although the sensing electrodes RE and the driving electrodes TE are formed in a diamond shape in a plan view in FIG. 5, embodiments of the present disclosure are not limited thereto.

In order to prevent the sensing electrodes RE and the driving electrodes TE from short-circuiting each other at their intersections, the driving electrodes TE adjacent to each other in the second direction (Y-axis direction) may be electrically connected through connection electrodes BE. In this case, the driving electrodes TE and the sensing electrodes RE may be disposed on one layer, and the connection electrodes BE may be disposed on a different layer from the driving electrodes TE and the sensing electrodes RE. In addition, the sensing electrodes RE electrically connected in the first direction (X-axis direction) and the driving electrodes TE electrically connected in the second direction (Y-axis direction) are electrically insulated from each other.

The touch lines TL and RL may be disposed in the touch peripheral area TPA. The touch lines TL and RL may include sensing lines RL connected to the sensing electrodes RE and first driving lines TL1 and second driving lines TL2 connected to the driving electrodes TE.

The sensing electrodes RE disposed on a right side of the touch sensor area TSA may be connected to the sensing lines RL. For example, rightmost sensing electrodes among the sensing electrodes RE electrically connected in the first direction (X-axis direction) may be connected to the sensing lines RL. The sensing lines RL may be connected to first touch pads TP1. Accordingly, the touch driving circuit 400 may be electrically connected to the sensing electrodes RE.

The driving electrodes TE disposed on a lower side of the touch sensor area TSA may be connected to the first driving lines TL1, and the driving electrodes TE disposed on an upper side of the touch sensor area TSA may be connected to the second driving lines TL2. For example, lowermost driving electrodes TE among the driving electrodes TE electrically connected in the second direction (Y-axis direction) may be connected to the first driving lines TL1, and uppermost driving electrodes TE may be connected to the second driving lines TL2. The second driving lines TL2 may be connected to the driving electrodes TE on the upper side of the touch sensor area TSA via a left side of the touch sensor area TSA. The first driving lines TL1 and the second driving lines TL2 may be connected to second touch pads TP2. Accordingly, the touch driving circuit 400 may be electrically connected to the driving electrodes TE.

The touch electrodes TE and RE may be driven in a mutual capacitance manner or a self-capacitance manner. When the touch electrodes TE and RE are driven in the mutual capacitance manner, driving signals are supplied to the driving electrodes TE through the first driving lines TL1 and the second driving lines TL2 to charge mutual capacitances formed at the intersections of the sensing electrodes RE and the driving electrodes TE. Then, charge change amounts of the sensing electrodes RE are measured through the sensing lines RL, and whether a touch has been input is determined according to the charge change amounts of the sensing electrodes RE. Each of the driving signals may be a signal having a plurality of driving pulses.

When the touch electrodes TE and RE are driven in a self-capacitance manner, driving signals are supplied to all of the driving electrodes TE and the sensing electrodes RE through the first driving lines TL1, the second driving lines TL2, and the sensing lines RL to charge self-capacitances of the driving electrodes TE and the sensing electrodes RE. Then, charge change amounts of the self-capacitances of the driving electrodes TE and the sensing electrodes RE are measured through the first driving lines TL1, the second driving lines TL2 and the sensing lines RL, and whether a touch has been input is determined according to the charge change amounts of the self-capacitances.

The driving electrodes TE, the sensing electrodes RE, and the connection electrodes BE may be formed as mesh-shaped electrodes as illustrated in FIG. 5. When the touch sensor layer TSL including the driving electrodes TE and the sensing electrodes RE is formed directly on the thin-film encapsulation layer TFEL as illustrated in FIG. 3, a distance between the second electrode of the light emitting element layer EML and the driving electrodes TE or the sensing electrodes RE of the touch sensor layer TSL is small. Therefore, a large parasitic capacitance may be formed between the second electrode of the light emitting element layer EML and the driving electrodes TE or the sensing electrodes RE of the touch sensor layer TSL. Hence, in order to reduce the parasitic capacitance, the driving electrodes TE and the sensing electrodes RE may be formed as mesh-shaped electrodes as illustrated in FIG. 5 rather than as non-patterned electrodes of a transparent oxide conductive layer such as ITO or IZO.

A first guard line GL1 may be disposed outside an outermost sensing line RL among the sensing lines RL. In addition, a first ground line GRL1 may be disposed outside the first guard line GL1. That is, the first guard line GL1 may be disposed on a right side of a rightmost sensing line RL among the sensing lines RL, and the first ground line GRL1 may be disposed on a right side of the first guard line GL1.

A second guard line GL2 may be disposed between an innermost sensing line RL among the sensing lines RL and a rightmost first driving line TL1 among the first driving lines TL1. In addition, the second guard line GL2 may be disposed between the rightmost first driving line TL1 among the first driving lines TL1 and a second ground line GRL2. Furthermore, a third guard line GL3 may be disposed between the innermost sensing line RL among the sensing lines RL and the second ground line GRL2. The second ground line GRL2 may be connected to a leftmost first touch pad among the first touch pads TP1 and a rightmost second touch pad among the second touch pads TP2.

A fourth guard line GL4 may be disposed outside an outermost second driving line TL2 among the second driving lines TL2. In addition, a third ground line GRL3 may be disposed outside the fourth guard line GL4. That is, the fourth guard line GL4 may be disposed on left and upper sides of a leftmost and uppermost second driving line TL2 among the second driving lines TL2, and the third ground line GRL3 may be disposed on left and upper sides of the fourth guard line GL4.

A fifth guard line GL5 may be disposed inside an innermost second driving line TL2 among the second driving lines TL2. That is, the fifth guard line GL5 may be disposed between a rightmost second driving line TL2 among the second driving lines TL2 and the touch electrodes TE and RE.

According to the embodiment illustrated in FIG. 5, the first ground line GRL1, the second ground line GRL2, and the third ground line GRL3 are disposed on uppermost, leftmost, and rightmost sides of the display panel 100. In addition, a ground voltage is applied to the first ground line GRL1, the second ground line GRL2, and the third ground line GRL3. Accordingly, when static electricity is applied from the outside, it may be discharged to the first ground line GRL1, the second ground line GRL2, and the third ground line GRL3.

In addition, according to the embodiment illustrated in FIG. 5, since the first guard line GL1 is disposed between the outermost sensing line RL and the first ground line GRL1, it may minimize the effect of a voltage change of the first ground line GRL1 on the outermost sensing line RL. The second guard line GL2 is disposed between the innermost sensing line RL and an outermost first driving line TL1. Therefore, the second guard line GL2 may minimize the effect of voltage changes of the innermost sensing line RL and the leftmost first driving line TL on each other. Since the third guard line GL3 is disposed between the innermost sensing line RL and the second ground line GRL2, it may minimize the effect of a voltage change of the second ground line GRL2 on the innermost sensing line RL. Since the fourth guard line GL4 is disposed between the outermost second driving line TL2 and the third ground line GRL3, it may minimize the effect of a voltage change of the third ground line GRL3 on the second driving line TL2. Since the fifth guard line GL5 is disposed between the innermost second driving line TL2 and the touch electrodes TE and RE, it may minimize the effect of the innermost second driving line TL2 and the touch electrodes TE and RE on each other.

When the touch electrodes TE and RE are driven in a mutual capacitance manner, a ground voltage may be applied to the first guard line GL1, the second guard line GL2, the third guard line GL3, the fourth guard line GL4, and the fifth guard line GL5. In addition, when the touch electrodes TE and RE are driven in a self-capacitance manner, the same driving signals as the driving signals transmitted to the first driving lines TL1, the second driving lines TL2, and the sensing lines RL may be transmitted to the first guard line GL1, the second guard line GL2, the third guard line GL3, the fourth guard line GL4, and the fifth guard line GL5.

FIG. 6 is a plan view illustrating an example of subpixels of FIG. 4 and a first touch metal layer of FIG. 5.

Referring to FIG. 6, the subpixels may include first subpixels RP, second subpixels GP, and third subpixels BP. Each of the first subpixels RP may display a first color, each of the second subpixels GP may display a second color, and each of the third subpixels BP may display a third color. The first color may be red, the second color may be green, and the third color may be blue, but embodiments of the present disclosure are not limited thereto.

The display panel 100 may express a white gray level in units of pixels P. One first subpixel RP, two second subpixels GP, and one third subpixel BP may be defined as one pixel P. In addition, the first subpixel RP, the second subpixels GP, and the third subpixel BP defined as one pixel P may be disposed in a rhombus shape as illustrated in FIG. 6.

In the display panel 100, the number of first subpixels RP and the number of third subpixels BP may be equal. In the display panel 100, the number of second subpixels GP may be twice the number of first subpixels RP and twice the number of third subpixels BP. In addition, in the display panel 100, the number of second subpixels GP may be equal to the sum of the number of first subpixels RP and the number of third subpixels BP.

In FIG. 6, the first subpixels RP, the second subpixels GP, and the third subpixels BP are formed in a rhombus shape when viewed in a plan view. However, embodiments of the present disclosure are not limited thereto. That is, the first subpixels RP, the second subpixels GP, and the third subpixels BP may also be formed in a rectangular or square shape when viewed in a plan view or may be formed in a polygonal shape other than a quadrangular shape, or in a circular or elliptical shape. In addition, the shape of the first subpixels RP, the shape of the second subpixels GP, and the shape of the third subpixels BP may be different from each other.

In FIG. 6, the size of the first subpixels RP, the size of the second subpixels GP, and the size of the third subpixels BP are the same as each other when viewed in a plan view. However, embodiments of the present disclosure are not limited thereto. That is, the size of the first subpixels RP, the size of the second subpixels GP, and the size of the third subpixels BP may also be different from each other when viewed in a plan view. For example, when viewed in a plan view, the size of the first subpixels RP may be larger than the size of the second subpixels GP, and the size of the third subpixels BP may be larger than the size of the second subpixels GP. In addition, when viewed in a plan view, the size of the first subpixels RP may be substantially the same as the size of the third subpixels BP or may be smaller than the size of the third subpixels BP.

First total reflection layers 210 do not overlap the first subpixels RP, the second subpixels GP, and the third subpixels BP. When viewed in a plan view, the first total reflection layers 210 may surround the subpixels RP, GP and BP, respectively.

The planar shape of the first total reflection layers 210 may depend on the shape of the subpixels RP, GP and BP. For example, when the shape of the first subpixels RP, the shape of the second subpixels GP, and the shape of the third subpixels BP are the same, the shape of the first total reflection layers 210 surrounding the first subpixels RP, the shape of the first total reflection layers 210 surrounding the second subpixels GP, and the shape of the first total reflection layers 210 surrounding the third subpixels BP may be the same. Alternatively, when the shape of the first subpixels RP, the shape of the second subpixels GP, and the shape of the third subpixels BP are different from each other, the shape of the first total reflection layers 210 surrounding the first subpixels RP, the shape of the first total reflection layers 210 surrounding the second subpixels GP, and the shape of the first total reflection layers 210 surrounding the third subpixels BP may be different from each other.

When viewed in a plan view, the size of the first total reflection layers 210 may depend on the size of the subpixels RP, GP and BP. For example, when the size of the first subpixels RP, the size of the second subpixels GP, and the size of the third subpixels BP are substantially the same in a plan view, the size of the first total reflection layers 210 surrounding the first subpixels RP, the size of the first total reflection layers 210 surrounding the second subpixels GP, and the size of the first total reflection layers 210 surrounding the third subpixels BP may be the same. Alternatively, when the size of the first subpixels RP, the size of the second subpixels GP, and the size of the third subpixels BP are different from each other in a plan view, the size of the first total reflection layers 210 surrounding the first subpixels RP, the size of the first total reflection layers 210 surrounding the second subpixels GP, and the size of the first total reflection layers 210 surrounding the third subpixels BP may be different from each other.

A driving electrode TE may surround the first total reflection layers 210 when viewed in a plan view. The driving electrode TE does not overlap the first subpixels RP, the second subpixels GP, and the third subpixels BP. In addition, the driving electrode TE does not overlap the first total reflection layers 210. The driving electrode TE may be formed in a mesh shape and disposed between the subpixels RP, GP and BP. Accordingly, it is possible to prevent an opening area of each of the subpixels RP, GP and BP from being reduced by the driving electrode TE. In addition, since an overlap area between the driving electrode TE and the second electrode 173 can be reduced, parasitic capacitance between the driving electrode TE and the second electrode 173 can be reduced. A sensing electrode RE may be formed substantially the same as the driving electrode TE, and thus a detailed description of the sensing electrode RE is omitted.

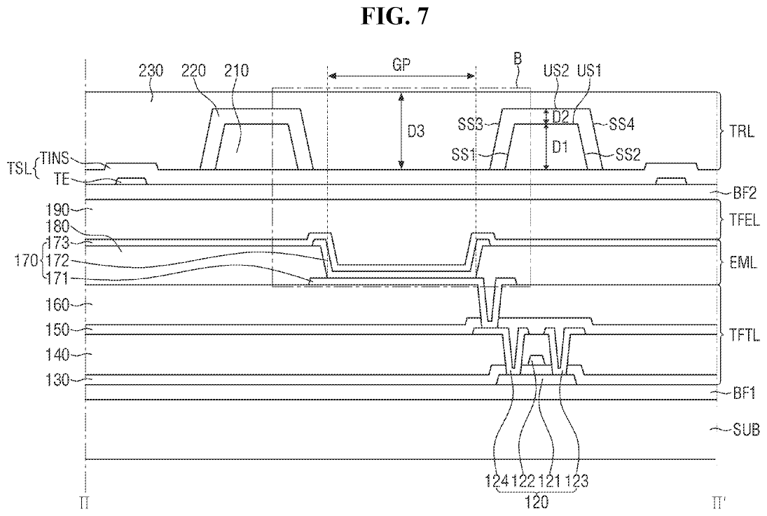

FIG. 7 is a cross-sectional view illustrating an example taken along line II-II′ of FIG. 6.

Referring to FIG. 7, the thin-film transistor layer TFTL is formed on the substrate SUB. The thin-film transistor layer TFTL includes thin-film transistors 120, a gate insulating layer 130, an interlayer insulating film 140, a protective layer 150, and a planarization layer 160.

A first buffer layer BF1 may be formed on a surface of the substrate SUB. The first buffer layer BF1 may be formed on the surface of the substrate SUB to protect the thin-film transistors 120 and an organic light emitting layer 172 of the light emitting element layer EML from moisture introduced through the substrate SUB, which is vulnerable to moisture penetration. The first buffer layer BF1 may be composed of a plurality of inorganic layers stacked alternately. For example, the first buffer layer BF1 may be a multilayer in which one or more inorganic layers selected from a silicon nitride layer, a silicon oxynitride layer, a silicon oxide layer, a titanium oxide layer, and an aluminum oxide layer are alternately stacked. The first buffer layer BF1 can be omitted in an embodiment.

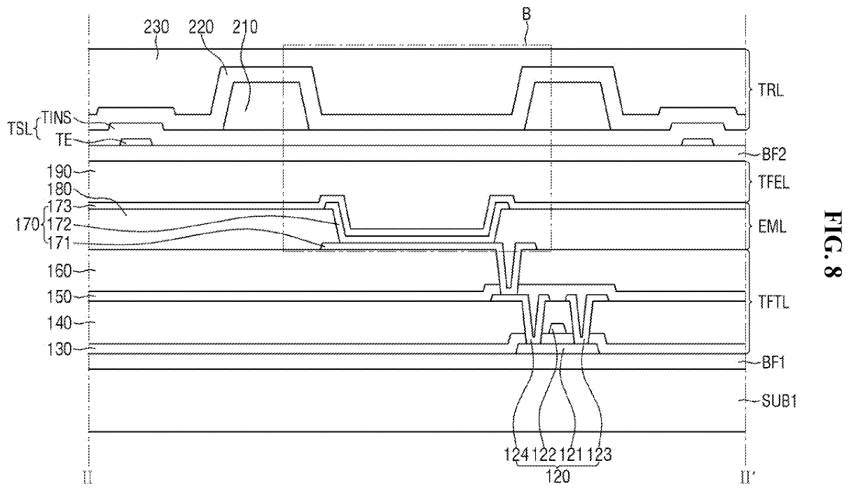

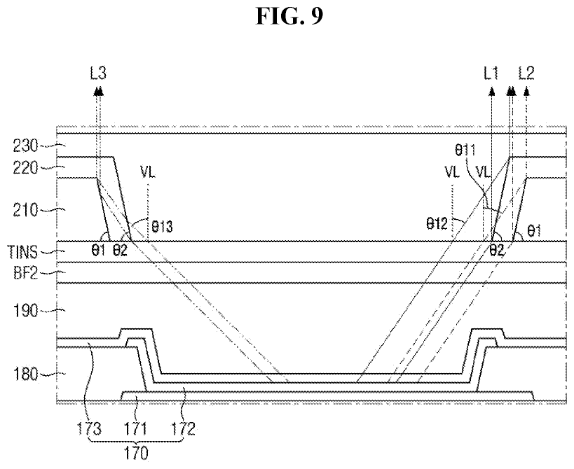

The thin-film transistors 120 are formed on the first buffer layer BF1. Each of the thin-film transistors 120 includes an active layer 121, a gate electrode 122, a source electrode 123, and a drain electrode 124. In FIG. 9, each of the thin-film transistors 120 is formed as a top-gate type in which the gate electrode 122 is located above the active layer 121. However, embodiments of the present disclosure are not limited thereto. That is, each of the thin-film transistors 120 may also be formed as a bottom-gate type in which the gate electrode 122 is located below the active layer 121 or a double-gate type in which the gate electrode 122 is located both above and below the active layer 121.

The active layer 121 is formed on the first buffer layer BF1. The active layer 121 may include polycrystalline silicon, monocrystalline silicon, low-temperature polycrystalline silicon, amorphous silicon, or an oxide semiconductor. Examples of the oxide semiconductor may include binary compounds (ABx), ternary compounds (ABxCy) and quaternary compounds (ABxCyDz) containing indium, zinc, gallium, tin, titanium, aluminum, hafnium (Hf), zirconium (Zr), magnesium (Mg), etc. For example, the active layer 121 may include ITZO (an oxide including indium, tin, and titanium) or IGZO (an oxide including indium, gallium, and tin). A light blocking layer may be formed between the buffer layer and the active layer 121 to block external light from entering the active layer 121.

The gate insulating layer 130 may be formed on the active layer 121. The gate insulating layer 130 may be made of an inorganic layer such as a silicon nitride layer, a silicon oxynitride layer, a silicon oxide layer, a titanium oxide layer, or an aluminum oxide layer.

The gate electrode 122 and a gate line may be formed on the gate insulating layer 130. Each of the gate electrode 122 and the gate line may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

The interlayer insulating film 140 may be formed on the gate electrode 122 and the gate line. The interlayer insulating film 140 may be made of an inorganic layer such as a silicon nitride layer, a silicon oxynitride layer, a silicon oxide layer, a titanium oxide layer, or an aluminum oxide layer.

The source electrode 123 and the drain electrode 124 may be formed on the interlayer insulating film 140. Each of the source electrode 123 and the drain electrode 124 may be connected to the active layer 121 through a contact hole penetrating the gate insulating layer 130 and the interlayer insulating film 140. Each of the source electrode 123 and the drain electrode 124 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

The protective layer 150 for insulating the thin-film transistors 120 may be formed on the source electrode 123 and the drain electrode 124. The protective layer 150 may be made of an inorganic layer such as a silicon nitride layer, a silicon oxynitride layer, a silicon oxide layer, a titanium oxide layer, or an aluminum oxide layer.

The planarization layer 160 may be formed on the protective layer 150 to planarize steps due to the thin-film transistors 120. The planarization layer 160 may be made of an organic layer such as acryl resin, epoxy resin, phenolic resin, polyamide resin, or polyimide resin.

The light emitting element layer EML is formed on the thin-film transistor layer TFTL. The light emitting element layer EML includes light emitting elements 170 and a pixel defining layer 180.

The light emitting elements 170 and the pixel defining layer 180 are formed on the planarization layer 160. Each of the light emitting elements 170 may include a first electrode 171, the organic light emitting layer 172, and the second electrode 173.

The first electrode 171 may be formed on the planarization layer 160. The first electrode 171 is connected to the source electrode 123 of a thin-film transistor 120 through a contact hole penetrating the protective layer 150 and the planarization layer 160.

In a top emission structure in which light is emitted from the organic light emitting layer 172 toward the second electrode 173, the first electrode 171 may be made of a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

In a bottom emission structure in which light is emitted from the organic light emitting layer 172 toward the first electrode 171, the first electrode 171 may be made of a transparent conductive material (TCO) capable of transmitting light, such as ITO or IZO, or a semi-transmissive conductive material such as magnesium (Mg), silver (Ag) or an alloy of Mg and Ag. In this case, when the first electrode 171 is made of a semi-transmissive conductive material, light output efficiency may be increased by a microcavity.

The pixel defining layer 180 may be formed on the planarization layer 160 to separate the first electrode 171 from another first electrode 171 so as to serve as a pixel defining layer for defining the subpixels RP, GP and BP. The pixel defining layer 180 may cover edges of the first electrode 171. The pixel defining layer 180 may be made of an organic layer such as acryl resin, epoxy resin, phenolic resin, polyamide resin, or polyimide resin.

Each of the subpixels RP, GP and BP is an area where the first electrode 171, the organic light emitting layer 172, and the second electrode 173 are sequentially stacked so that holes from the first electrode 171 and electrons from the second electrode 173 combine together in the organic light emitting layer 172 to emit light. Each of the subpixels RP, GP and BP may include the light emitting element 170.

The organic light emitting layer 172 is formed on the first electrode 171 and the pixel defining layer 180. The organic light emitting layer 172 may include an organic material to emit light of a predetermined color. For example, the organic light emitting layer 172 may include a hole transporting layer, an organic material layer, and an electron transporting layer. In this case, the organic light emitting layers 172 of the first subpixels RP may emit light of the first color, the organic light emitting layers 172 of the second subpixels GP may emit light of the second color, and the organic light emitting layers 172 of the third subpixels BP may emit light of the third color. The first color may be red, the second color may be green, and the third color may be blue, but embodiments of the present disclosure are not limited thereto.

Alternatively, the organic light emitting layer 172 of each of the subpixels RP, GP and BP may emit white light. In this case, the first subpixels RP may overlap color filter layers of the first color, the second subpixels GP may overlap color filter layers of the second color, and the third subpixels BP may overlap color filter layers of the third color.

The second electrode 173 is formed on the organic light emitting layer 172. The second electrode 173 may be formed to cover the organic light emitting layer 172. The second electrode 173 may be a common layer formed in common to the subpixels RP, GP and BP. A capping layer may be formed on the second electrode 173.

In the top emission structure, the second electrode 173 may be made of a transparent conductive material (TCO) capable of transmitting light, such as ITO or IZO, or a semi-transmissive conductive material such as magnesium (Mg), silver (Ag) or an alloy of Mg and Ag. When the second electrode 173 is made of a semi-transmissive conductive material, the light output efficiency may be increased by a microcavity.

In the bottom emission structure, the second electrode 173 may be made of a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The thin-film encapsulation layer TFEL is formed on the light emitting element layer EML. The thin-film encapsulation layer TFEL includes an encapsulation layer 190.

The encapsulation layer 190 is disposed on the second electrode 173. The encapsulation layer 190 may include at least one inorganic layer to prevent oxygen or moisture from penetrating into the organic light emitting layer 172 and the second electrode 173. In addition, the encapsulation layer 190 may include at least one organic layer to protect the light emitting element layer EML from foreign substances such as dust. For example, the encapsulation layer 190 may include a first inorganic layer disposed on the second electrode 173, an organic layer disposed on the first inorganic layer, and a second inorganic layer disposed on the organic layer. The first inorganic layer and the second inorganic layer may be made of, but not limited to, a silicon nitride layer, a silicon oxynitride layer, a silicon oxide layer, a titanium oxide layer, or an aluminum oxide layer. The organic layer may be made of, but not limited to, acryl resin, epoxy resin, phenolic resin, polyamide resin, polyimide resin, etc.

A second buffer layer BF2 is formed on the thin-film encapsulation layer TFEL. The second buffer layer BF2 may be composed of a plurality of inorganic layers stacked alternately. For example, the second buffer layer BF2 may be a multilayer in which one or more inorganic layers selected from a silicon nitride layer, a silicon oxynitride layer, a silicon oxide layer, a titanium oxide layer, and an aluminum oxide layer are alternately stacked. The second buffer layer BF2 can be omitted in an embodiment.

The touch sensor layer TSL is formed on the second buffer layer BF2. The touch sensor layer TSL may include the driving electrodes TE, the sensing electrodes, the connection electrodes BE, the first driving lines TL1, the second driving lines TL2, the sensing lines RL, the guard lines GL1 through GL5, and the ground lines GRL1 through GRL3, as illustrated in FIG. 5. In FIG. 7, only a driving electrode TE of the touch sensor layer TSL is illustrated for ease of description.

The driving electrodes TE are formed on the second buffer layer BF2. In addition to the driving electrodes TE, the sensing electrodes RE, the first driving lines TL1, the second driving lines TL2, the sensing lines RL, the guard lines GL1 through GL5, and the ground lines GRL1 through GRL3 may be disposed on the encapsulation layer 190. That is, the driving electrodes TE, the sensing electrodes RE, the first driving lines TL1, the second driving lines TL2, the sensing lines RL, the guard lines GL1 through GL5, and the ground lines GRL1 through GRL3 excluding the connection electrodes BE may be disposed on the same layer and may be made of the same material. The driving electrodes TE, the sensing electrodes RE, the first driving lines TL1, the second driving lines TL2, the sensing lines RL, the guard lines GL1 through GL5, and the ground lines GRL1 through GRL3 may be made of, but not limited to, a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

A touch insulating layer TINS is formed on the driving electrodes TE. The touch insulating layer TINS may be made of an inorganic layer such as a silicon nitride layer, a silicon oxynitride layer, a silicon oxide layer, a titanium oxide layer, or an aluminum oxide layer.

The connection electrodes BE illustrated in FIG. 5 may be formed on the touch insulating layer TINS. Each of the connection electrodes BE may be connected to the driving electrodes TE through contact holes penetrating the touch insulating layer TINS. The driving electrodes TE disposed in the second direction (Y-axis direction) may be electrically connected by the connection electrodes BE. The connection electrodes BE may be made of, but not limited to, a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

In an embodiment according to FIG. 7, the driving electrodes TE, the sensing electrodes RE, the first driving lines TL1, the second driving lines TL2, the sensing lines RL, the guard lines GL1 through GL5, and the ground lines GRL1 through GRL3 are formed on the second buffer layer BF2, and the connection electrodes BE are formed on the touch insulating layer TINS. However, embodiments of the present disclosure are not limited thereto. For example, the connection electrodes BE may be formed on the second buffer layer BF2, and the driving electrodes TE, the sensing electrodes RE, the first driving lines TL1, the second driving lines TL2, the sensing lines RL, the guard lines GL1 through GL5, and the ground lines GRL1 through GRL3 may be formed on the touch insulating layer TINS.

The total reflection layer TRL is disposed on the touch sensor layer TSL. The total reflection layer TRL is a layer that totally reflects light travelling in the lateral direction rather than the upward direction (Z-axis direction) among light from the subpixels RP, GP and BP, so that the light can travel in the upward direction (Z-axis direction). The total reflection layer TRL may include a first total reflection layer 210, a second total reflection layer 220, and a high refractive planarization layer 230.

The first total reflection layer 210 may be disposed on the touch insulating layer TINS. The first total reflection layer 210 overlaps the pixel defining layer 180 and does not overlap the subpixels RP, GP and BP. The first total reflection layer 210 may include a first inclined surface SS1 adjacent to each of the subpixels RP, GP and BP, a second inclined surface SS2 facing the first inclined surface SS1, and a first upper surface US1 connecting the first inclined surface SS1 and the second inclined surface SS2. The first inclined surface SS1 of the first total reflection layer 210 may be an inner surface of the first total reflection layer 210, and the second inclined surface SS2 may be an outer surface of the first total reflection layer 210.

A first taper angle θ1 of the first inclined surface SS1 of the first total reflection layer 210 may be 90 degrees or less. Therefore, the first inclined surface SS1 of the first total reflection layer 210 may be regularly tapered. The first taper angle θ1 is an inclination angle of the first inclined surface SS1 and indicates an angle formed by the touch insulating layer TINS and the first inclined surface SS1 of the first total reflection layer 210.

The first total reflection layer 210 may be made of an organic layer or may be made of an organic layer including inorganic particles. The organic layer may be, but is not limited to, acryl resin, epoxy resin, phenolic resin, polyamide resin, or polyimide resin. The inorganic particles may be, but are not limited to, metal particles.

The greater the thickness D1 of the first total reflection layer 210, the higher the proportion of light totally reflected from the first inclined surface SS1 of the first total reflection layer 210 to travel in the upward direction (Z-axis direction) among the light of the subpixels RP, GP and BP. Therefore, to increase the light output efficiency of the subpixels RP, GP and BP, the thickness D1 of the first total reflection layer 210 may be 1.5 um or more, preferably, about 3 um.

The second total reflection layer 220 may be disposed on the first total reflection layer 210. The second total reflection layer 220 overlaps the pixel defining layer 180 and does not overlap the subpixels RP, GP and BP. The second total reflection layer 220 may include a third inclined surface SS3 disposed on the first inclined surface SS1, a fourth inclined surface SS4 disposed on the second inclined surface SS2, and a second upper surface US2 disposed on the first upper surface US1. The second upper surface US2 may connect the third inclined surface SS3 and the fourth inclined surface SS4. The third inclined surface SS3 of the second total reflection layer 220 may be an inner surface of the second total reflection layer 220, and the fourth inclined surface SS4 may be an outer surface.

A second taper angle θ2 of the third inclined surface SS3 of the second total reflection layer 220 may be 90 degrees or less. Therefore, the third inclined surface SS3 of the second total reflection layer 220 may be regularly tapered. The second taper angle θ2 is an inclination angle of the third inclined surface SS3 and indicates an angle formed by the touch insulating layer TINS and the third inclined surface SS3 of the second total reflection layer 220.

The second total reflection layer 220 may be made of an inorganic layer, an organic layer, or an organic layer including inorganic particles. The inorganic layer may be, but is not limited to, a silicon nitride layer, a silicon oxynitride layer, a silicon oxide layer, a titanium oxide layer, or an aluminum oxide layer. The organic layer may be, but is not limited to, acryl resin, epoxy resin, phenolic resin, polyamide resin, or polyimide resin. The inorganic particles may be, but are not limited to, metal particles.

A refractive index of the second total reflection layer 220 may be greater than a refractive index of the first total reflection layer 210 so that the light of the subpixels RP, GP and BP can be totally reflected from the first inclined surface SS1 of the first total reflection layer 210 to travel in the upward direction (Z-axis direction).

When a thickness D2 of the second total reflection layer 220 is equal to the thickness D1 of the first total reflection layer 210 or greater than the thickness of the first total reflection layer 210, the proportion of light refracted from the third inclined surface SS3 of the second total reflection layer 220 and then totally reflected from the first inclined surface SS1 of the first total reflection layer 210 to travel in the upward direction (Z-axis direction) among the light of the subpixels RP, GP and BP may decrease. Therefore, the thickness D2 of the second total reflection layer 220 may be smaller than the thickness D1 of the first total reflection layer 210. The thickness D1 of the first total reflection layer 210 may indicate a maximum thickness of the first total reflection layer 210, and the thickness D2 of the second total reflection layer 220 may indicate a maximum thickness of the second total reflection layer 220.

Although the second total reflection layer 220 is disposed on the first inclined surface SS1, the second inclined surface SS2, and the first upper surface US1 of the first total reflection layer 210 in FIG. 7, embodiments of the present disclosure are not limited thereto. The second total reflection layer 220 may also be disposed only on the first inclined surface SS1 and the second inclined surface SS2 of the first total reflection layer 210.

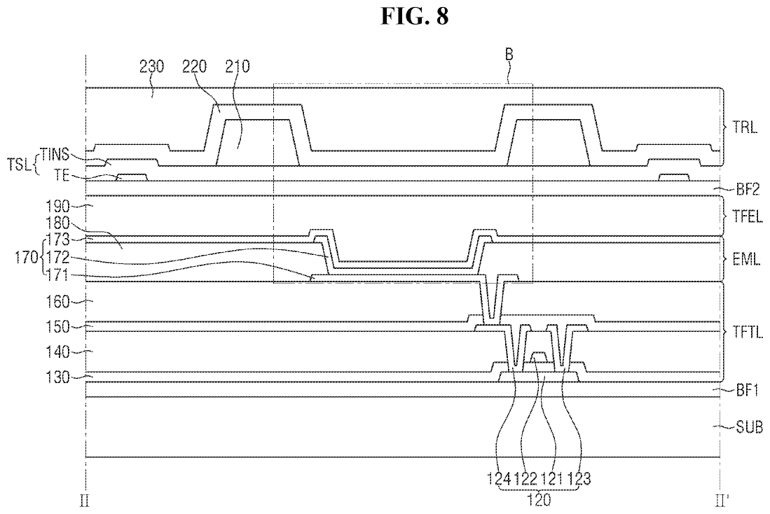

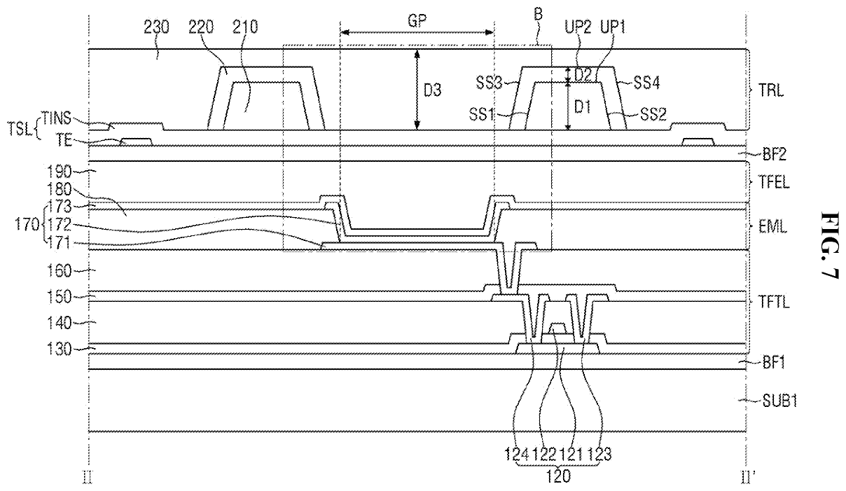

The second total reflection layer 220 may be formed to cover the touch insulating layer TINS not covered by the first total reflection layer 210 as illustrated in FIG. 8. In this case, since the second total reflection layer 220 can be formed without a separate mask process, the manufacturing cost can be reduced.

The high refractive planarization layer 230 may be formed on the touch insulating layer TINS and the second total reflection layer 220 as illustrated in FIG. 7 or may be formed on the second total reflection layer 220 as illustrated in FIG. 8. The high refractive planarization layer 230 serves to planarize steps formed by the first total reflection layer 210 and the second total reflection layer 220. To this end, a thickness D3 of the high refractive planarization layer 230 may be greater than the thickness D1 of the first total reflection layer 210. For example, the thickness D3 of the high refractive planarization layer 230 may be about 5 um. The thickness D3 of the high refractive planarization layer 230 may indicate a maximum thickness of the high refractive planarization layer 230.

The high refractive planarization layer 230 may be made of an organic layer or may be made of an organic layer including inorganic particles. The organic layer may be, but is not limited to, acryl resin, epoxy resin, phenolic resin, polyamide resin, or polyimide resin. The inorganic particles may be, but are not limited to, metal particles.

A refractive index of the high refractive planarization layer 230 may be greater than the refractive index of the second total reflection layer 220 so that the light of the subpixels RP, GP and BP can be totally reflected from the second inclined surface SS2 of the second total reflection layer 220 to travel in the upward direction (Z-axis direction).

According to the embodiment illustrated in FIG. 7, light travelling in the lateral direction rather than the upward direction (Z-axis direction) among the light of the subpixels RP, GP and BP may be totally reflected from the third inclined surface SS3 of the second total reflection layer 220, may be totally reflected from the first inclined surface SS1 of the first total reflection layer 210, or may be refracted from the third inclined surface SS3 of the second total reflection layer 220 and then totally reflected from the first inclined surface SS1 of the first total reflection layer 210 to travel in the upward direction. Therefore, it is possible to increase the light output efficiency of the subpixels RP, GP and BP, thereby increasing the life of the organic light emitting elements and reducing the power consumption of the organic light emitting display.

FIG. 9 is a cross-sectional view illustrating an example of area B of FIG. 7 in detail.

Referring to FIG. 9, first light L1 is light that is output at a first output angle θ11 at an interface between the touch insulating layer TINS and the high refractive planarization layer 230 and then totally reflected from the first inclined surface SS1 of the first total reflection layer 210. Light of the organic light emitting layer 172 of a second subpixel OP may be refracted at the interface between the touch insulating layer TINS and the high refractive planarization layer 230 due to a difference in refractive index between the touch insulating layer TINS and the high refractive planarization layer 230. Therefore, the first output angle θ11 refers to an angle formed by a normal line VL drawn perpendicularly upward and the first light L1 at the interface between the touch insulating layer TINS and the high refractive planarization layer 230.

Second light L2 is light that is output at a second output angle θ12 at the interface between the touch insulating layer TINS and the high refractive planarization layer 230 and then totally reflected from the third inclined surface SS3 of the second total reflection layer 220. The second output angle θ12 refers to an angle formed by the normal line VL drawn perpendicularly upward and the second light L2 at the interface between the touch insulating layer TINS and the high refractive planarization layer 230.

The first output angle θ11 may be calculated as in Equation 1, and the second output angle θ12 may be calculated as in Equation 2:

θ1=90−θ11/2 (1)

θ2=90−θ12/2 (2).

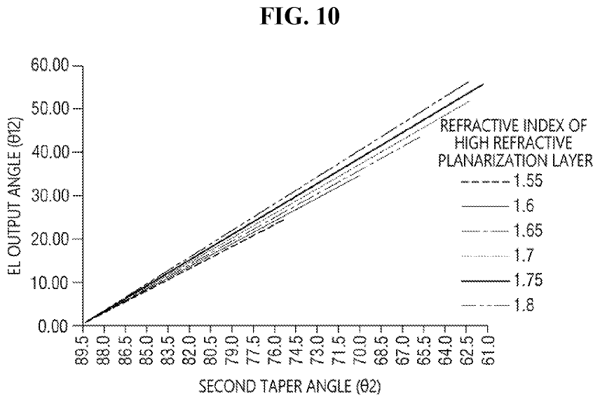

FIG. 10 illustrates the second output angle θ12 with respect to the second taper angle θ2 of the second total reflection layer 220 calculated by Equation 2. In FIG. 10, the x-axis represents the second taper angle θ2 of the second total reflection layer 220, and the y-axis represents the second output angle θ12.

Since the refractive index of the high refractive planarization layer 230 is high, the first light L1 totally reflected from the first inclined surface SS1 of the first total reflection layer 210 and the second light L2 totally reflected from the third inclined surface SS3 of the second total reflection layer 220 may be refracted when they enter the high refractive planarization layer 230 or exit from the high refractive planarization layer 230. Therefore, the first output angle θ11 and the second output angle θ12 may be changed according to the refractive index of the high refractive planarization layer 230 as illustrated in FIG. 10. That is, the first output angle θ11 and the second output angle θ12 may increase as the refractive index of the high refractive planarization layer 230 increases.

As illustrated in FIG. 10, as the second taper angle θ2 of the second total reflection layer 220 increases, the second output angle θ12 increases. In addition, when the second taper angle θ2 of the second total reflection layer 220 and the refractive index of the second total reflection layer 220 are constant, the second output angle θ12 increases as the refractive index of the high refractive planarization layer 230 increases as illustrated in FIG. 10. That is, as the difference between the refractive index of the high refractive planarization layer 230 and the refractive index of the second total reflection layer 220 increases, the second output angle θ12 increases. For example, referring to FIG. 10, if the second taper angle θ2 of the second total reflection layer 220 is 75 degrees, and the refractive index of the second total reflection layer 220 is 1.5, when the refractive index of the high refractive planarization layer 230 is 1.8, the second output angle θ12 is about 30 degrees. On the other hand, when the refractive index of the high refractive planarization layer 230 is 1.55, the second output angle θ12 may be about 26 degrees.

Similar to FIG. 10, as the first taper angle θ1 of the first total reflection layer 210 increases, the first output angle θ11 increases. In addition, when the first taper angle θ1 of the first total reflection layer 210 and the refractive index of the first total reflection layer 210 are constant, the first output angle θ11 increases as the refractive index of the second total reflection layer 220 increases. As the difference between the refractive index of the second total reflection layer 220 and the refractive index of the first total reflection layer 210 increases, the first output angle θ11 increases.

Therefore, when the first taper angle θ1 of the first total reflection layer 210 is substantially equal to the second taper angle θ2 of the second total reflection layer 220, and the difference in refractive index between the first total reflection layer 210 and the second total reflection layer 220 is substantially equal to the difference in refractive index between the second total reflection layer 220 and the high refractive planarization layer 230, the first output angle θ11 and the second output angle θ12 may be substantially equal.

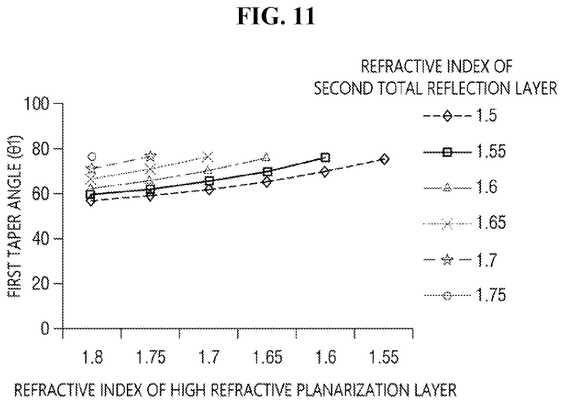

Furthermore, a minimum angle of the second taper angle θ2 of the second total reflection layer 220 for outputting the second light L2 may be changed according to the difference in refractive index between the second total reflection layer 220 and the high refractive planarization layer 230 as illustrated in FIG. 11. Specifically, the minimum angle of the second taper angle θ2 of the second total reflection layer 220 for outputting the second light L2 may increase as the difference in refractive index between the second total reflection layer 220 and the high refractive planarization layer 230 decreases.

Similar to FIG. 11, a minimum angle of the first taper angle θ1 of the first total reflection layer 210 for outputting the first light L1 may increase as the difference in refractive index between the first total reflection layer 210 and the second total reflection layer 220 decreases.

Third light L3 is light that is output at a third output angle θ13 at the interface between the touch insulating layer TINS and the high refractive planarization layer 230, refracted from the third inclined surface SS3 of the second total reflection layer 220, and then totally reflected from the first inclined surface SS1 of the first total reflection layer 210. The third output angle θ13 refers to an angle formed by the normal line VL drawn perpendicularly upward and the third light L3 at the interface between the touch insulating layer TINS and the high refractive planarization layer 230.

The third output angle θ13, the first taper angle θ1 of the first total reflection layer 210, and the second taper angle θ2 of the second total reflection layer 220 may be defined as Equation 3:

$$θ1 = ( arcsin ( \frac{n 3}{n 2} \times sin ( 180 - θ2 - θ13 ) \times \frac{180}{π} ) + θ2 ) / 2 \qquad ( 3 )$$

In Equation 3, n2 indicates the refractive index of the second total reflection layer 220, and n3 indicates the refractive index of the high refractive planarization layer 230.

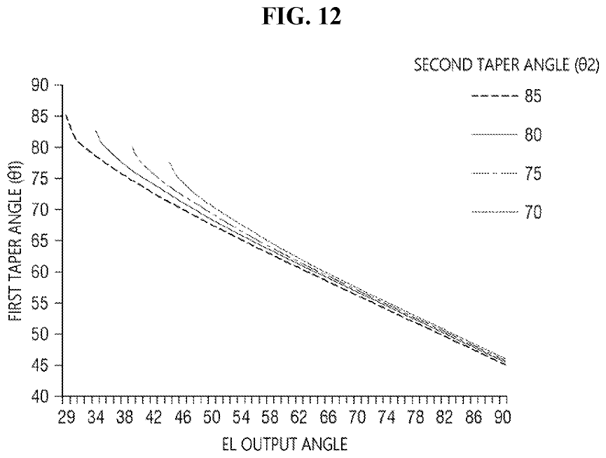

FIG. 12 illustrates the first taper angle θ1 of the first total reflection layer 210 with respect to the third output angle θ13 for each second taper angle θ2 of the second total reflection layer 220 calculated by Equation 3. In FIG. 12, the x-axis represents the third output angle θ13, and the y-axis represents the first taper angle θ1 of the first total reflection layer 210.

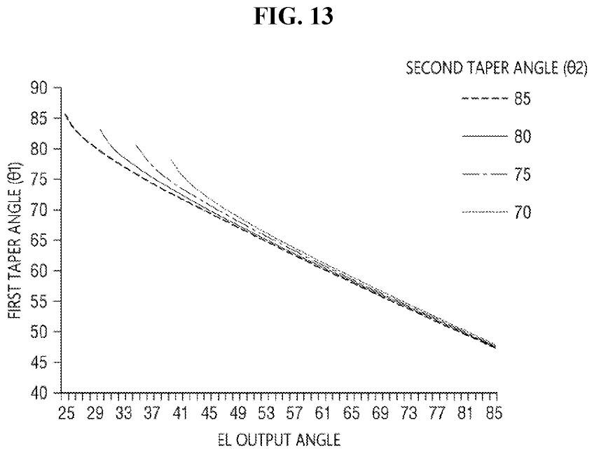

As illustrated in FIGS. 12 and 13, as the first taper angle θ1 of the first total reflection layer 210 increases, the third output angle θ13 decreases. In addition, as illustrated in FIGS. 12 and 13, as the second taper angle θ2 of the second total reflection layer 220 increases, the third output angle θ13 decreases.

In addition, as illustrated in FIGS. 12 and 13, as the difference in refractive index between the first total reflection layer 210 and the second total reflection layer 220 and the difference in refractive index between the second total reflection layer 220 and the high refractive planarization layer 230 increase, the third output angle θ13 decreases. For example, as illustrated in FIG. 12, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 75 degrees, and the second taper angle θ2 of the second total reflection layer 220 is 75 degrees, the third output angle θ13 may be about 43 degrees. On the other hand, as illustrated in FIG. 13, when the refractive index of the first total reflection layer 210 is 1.5, the refractive index of the second total reflection layer 220 is 1.6, the refractive index of the high refractive planarization layer 230 is 1.7, the first taper angle θ1 of the first total reflection layer 210 is 75 degrees, and the second taper angle θ2 of the second total reflection layer 220 is 75 degrees, the third output angle θ13 may be about 40 degrees.

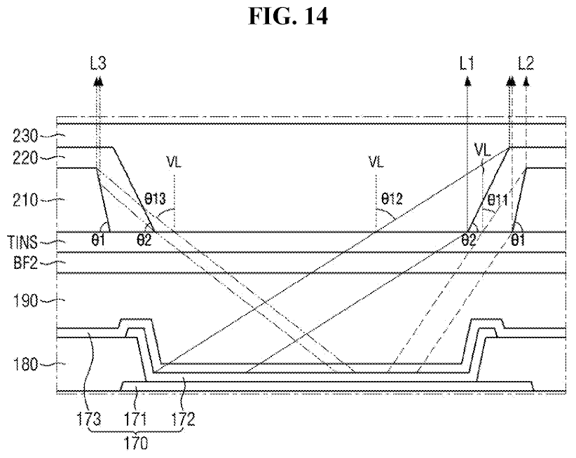

FIG. 14 is a cross-sectional view illustrating another example of area B of FIG. 7 in detail.

Referring to FIG. 14, the first taper angle θ1 of the first total reflection layer 210 may be greater than the second taper angle θ2 of the second total reflection layer 220. As the first taper angle θ1 of the first total reflection layer 210 increases, the first output angle θ11 of the first light L1 increases. As illustrated in FIG. 10, as the second taper angle θ2 of the second total reflection layer 220 increases, the second output angle θ12 of the second light L2 increases. Therefore, when the difference in refractive index between the first total reflection layer 210 and the second total reflection layer 220 is substantially equal to the difference in refractive index between the second total reflection layer 220 and the high refractive planarization layer 230, since the first taper angle θ1 of the first total reflection layer 210 is greater than the second taper angle θ2 of the second total reflection layer 220, the first output angle θ11 may be greater than the second output angle θ12.

In addition, as the first taper angle θ1 of the first total reflection layer 210 increases, the third output angle θ13 of the third light L3 decreases. As the second taper angle θ2 of the second total reflection layer 220 increases, the third output angle θ13 decreases. Therefore, when the difference in refractive index between the first total reflection layer 210 and the second total reflection layer 220 is substantially equal to the difference in refractive index between the second total reflection layer 220 and the high refractive planarization layer 230, since the second taper angle θ2 of the second total reflection layer 220 is smaller in the embodiment illustrated in FIG. 14 than in the embodiment illustrated in FIG. 9, the third output angle θ13 of the third light L3 may be greater in the embodiment illustrated in FIG. 14 than in the embodiment illustrated in FIG. 9.

For example, referring to FIG. 12, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 75 degrees, and the second taper angle θ2 of the second total reflection layer 220 is 70 degrees, the third output angle θ13 may be about 45 degrees. On the other hand, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 75 degrees, and the second taper angle θ2 of the second total reflection layer 220 is 75 degrees, the third output angle θ13 may be about 42 degrees.

In addition, as the difference in refractive index between the first total reflection layer 210 and the second total reflection layer 220 and the difference in refractive index between the second total reflection layer 220 and the high refractive planarization layer 230 increase, the third output angle θ13 of the third light L3 decreases. For example, referring to FIG. 12, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 75 degrees, and the second taper angle θ2 of the second total reflection layer 220 is 70 degrees, the third output angle θ13 may be about 45 degrees. On the other hand, when the refractive index of the first total reflection layer 210 is 1.5, the refractive index of the second total reflection layer 220 is 1.6, the refractive index of the high refractive planarization layer 230 is 1.7, the first taper angle θ1 of the first total reflection layer 210 is 75 degrees, and the second taper angle θ2 of the second total reflection layer 220 is 70 degrees, the third output angle θ13 may be about 42 degrees.

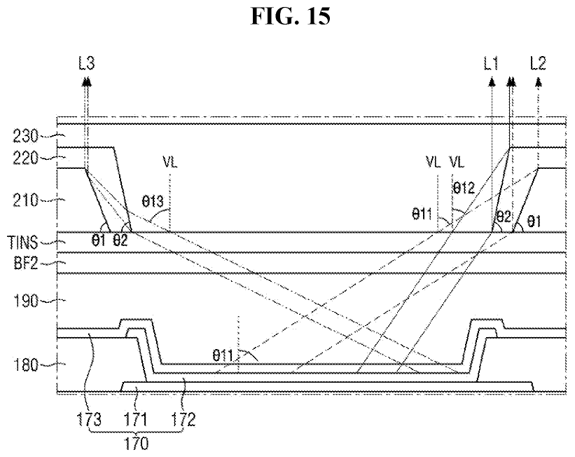

FIG. 15 is a cross-sectional view illustrating another example of area B of FIG. 7 in detail.

Referring to FIG. 15, the first taper angle θ1 of the first total reflection layer 210 may be smaller than the second taper angle θ2 of the second total reflection layer 220. As the first taper angle θ1 of the first total reflection layer 210 increases, the first output angle θ11 of the first light L1 increases. As illustrated in FIG. 10, as the second taper angle θ2 of the second total reflection layer 220 increases, the second output angle θ12 of the second light L2 increases. Therefore, when the difference in refractive index between the first total reflection layer 210 and the second total reflection layer 220 is substantially equal to the difference in refractive index between the second total reflection layer 220 and the high refractive planarization layer 230, since the first taper angle θ1 of the first total reflection layer 210 is smaller than the second taper angle θ2 of the second total reflection layer 220, the first output angle θ11 may be smaller than the second output angle θ12.

In addition, as the first taper angle θ1 of the first total reflection layer 210 increases, the third output angle θ13 of the third light L3 decreases. As the second taper angle θ2 of the second total reflection layer 220 increases, the third output angle θ13 of the third light L3 decreases. Therefore, when the difference in refractive index between the first total reflection layer 210 and the second total reflection layer 220 is substantially equal to the difference in refractive index between the second total reflection layer 220 and the high refractive planarization layer 230, since the first taper angle θ1 of the first total reflection layer 210 is smaller in the embodiment illustrated in FIG. 15 than in the embodiment illustrated in FIG. 9, the third output angle θ13 of the third light L3 may be greater in the embodiment illustrated in FIG. 15 than in the embodiment illustrated in FIG. 9.

For example, referring to FIG. 12, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 70 degrees, and the second taper angle θ2 of the second total reflection layer 220 is 75 degrees, the third output angle θ13 may be about 49 degrees. On the other hand, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 75 degrees, and the second taper angle θ2 of the second total reflection layer 220 is 75 degrees, the third output angle θ13 may be about 43 degrees.

In addition, as the difference in refractive index between the first total reflection layer 210 and the second total reflection layer 220 and the difference in refractive index between the second total reflection layer 220 and the high refractive planarization layer 230 increase, the third output angle θ13 of the third light L3 decreases. For example, referring to FIG. 12, when the refractive index of the first total reflection layer 210 is 1.5, the refractive index of the second total reflection layer 220 is 1.65, the refractive index of the high refractive planarization layer 230 is 1.8, the first taper angle θ1 of the first total reflection layer 210 is 70 degrees, and the second taper angle θ2 of the second total reflection layer 220 is 75 degrees, the third output angle θ13 may be about 49 degrees. On the other hand, when the refractive index of the first total reflection layer 210 is 1.5, the refractive index of the second total reflection layer 220 is 1.6, the refractive index of the high refractive planarization layer 230 is 1.7, the first taper angle θ1 of the first total reflection layer 210 is 70 degrees, and the second taper angle θ2 of the second total reflection layer 220 is 75 degrees, the third output angle θ13 may be about 47 degrees.

As described in FIGS. 9 through 15, the first output angle θ11 of the first light L1, the second output angle θ12 of the second light L2, and the third output angle θ13 of the third light L3 may be determined by the first taper angle θ1 of the first total reflection layer 210, the second taper angle θ2 of the second total reflection layer 220, the refractive index of the first total reflection layer 210, the refractive index of the second total reflection layer 220, and the refractive index of the high refractive planarization layer 230. If the first taper angle θ1 of the first total reflection layer 210, the second taper angle θ2 of the second total reflection layer 220, the refractive index of the first total reflection layer 210, the refractive index of the second total reflection layer 220, and the refractive index of the high refractive planarization layer 230 are appropriately set in advance through a preliminary experiment, the proportion of the first light L1, the second light L2, and the third light L3 can be increased, thereby increasing the light output efficiency of the subpixels RP, GP and BP. Accordingly, this cannot only increase the life of the organic light emitting elements, but also can reduce the power consumption of the organic light emitting display.

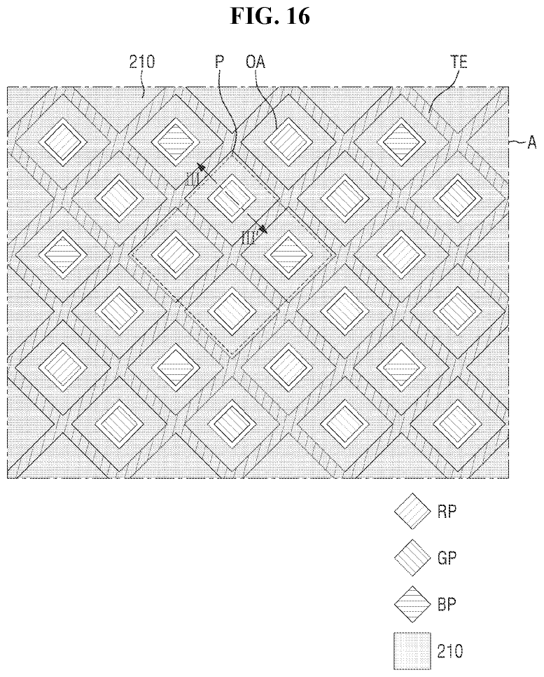

FIG. 16 is a plan view illustrating another example of the subpixels of FIG. 4 and the first touch metal layer of FIG. 5.

The embodiment illustrated in FIG. 16 is different from the embodiment illustrated in FIG. 6 in that a first total reflection layer 210 overlaps a driving electrode TE.

Referring to FIG. 16, the first total reflection layer 210 does not overlap first subpixels RP, second subpixels GP, and third subpixels BP when viewed in a plan view. The first total reflection layer 210 may include opening areas OA exposing the subpixels RP, GP and BP when viewed in a plan view.

The planar shape of the opening areas OA may depend on the shape of the subpixels RP, GP and BP. For example, when the shape of the first pixels RP, the shape of the second subpixels GP, and the shape of the third subpixels BP are the same, the shape of the opening areas OA exposing the first subpixels RP, the shape of the opening areas OA exposing the second subpixels GP, and the shape of the opening areas OA exposing the third subpixels BP may be the same. Alternatively, when the shape of the first subpixels RP, the shape of the second subpixels GP, and the shape of the third subpixels BP are different from each other, the shape of the opening areas OA exposing the first subpixels RP, the shape of the opening areas OA exposing the second subpixels GP, and the shape of the opening areas OA exposing the third subpixels BP may be different from each other.

The size of the opening areas OA may depend on the size of the subpixels RP, GP and BP when viewed in a plan view. For example, when the size of the first subpixels RP, the size of the second subpixels GP, and the size of the third subpixels BP are the same in a plan view, the size of the opening areas OA exposing the first subpixels RP, the size of the opening areas OA exposing the second subpixels GP, and the size of the opening areas OA exposing the third subpixels BP may be the same. Alternatively, when the size of the first subpixels RP, the size of the second subpixels GP, and the size of the third subpixels BP are different from each other in a plan view, the size of the opening areas OA exposing the first subpixels RP, the size of the opening areas OA exposing the second subpixels GP, and the size of the opening areas OA exposing the third subpixels BP may be different from each other.

The first total reflection layer 210 may overlap the driving electrode TE. Since a sensing electrode RE may be formed substantially the same as the driving electrode TE, the first total reflection layer 210 may overlap the sensing electrode RE. In addition, since a connection electrode BE overlaps the driving electrode TE and the sensing electrode RE, the first total reflection layer 210 may overlap the connection electrode BE.

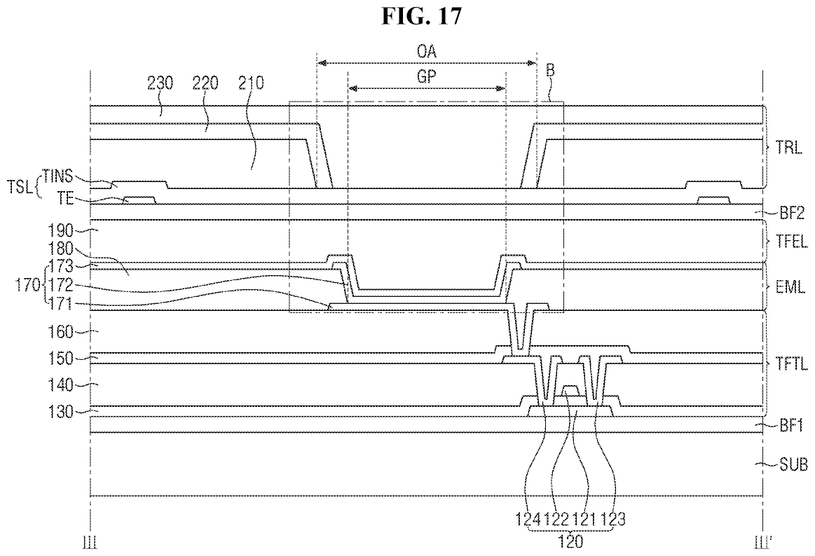

FIG. 17 is a cross-sectional view illustrating an example taken along line III-III′ of FIG. 16.

The embodiment illustrated in FIG. 17 is different from the embodiment illustrated in FIG. 7 in that the first total reflection layer 210 includes first inclined surfaces SS1 defining the opening area OA exposing each of the subpixels RP, GP and BP and that the first total reflection layer 210 is formed to cover the driving electrode TE.

Referring to FIG. 17, the first total reflection layer 210 may be formed to cover the driving electrode TE and a touch insulating layer TINS, except for the opening area OA exposing each of the subpixels RP, GP and BP as illustrated in FIG. 17.

Although a second total reflection layer 220 is disposed on the first inclined surfaces SS1 and a first upper surface US1 of the first total reflection layer 210 in FIG. 17, embodiments of the present disclosure are not limited thereto. That is, the second total reflection layer 220 may also be disposed on the first total reflection layer 210 and the touch insulating layer TINS exposed without being covered by the first total reflection layer 210.

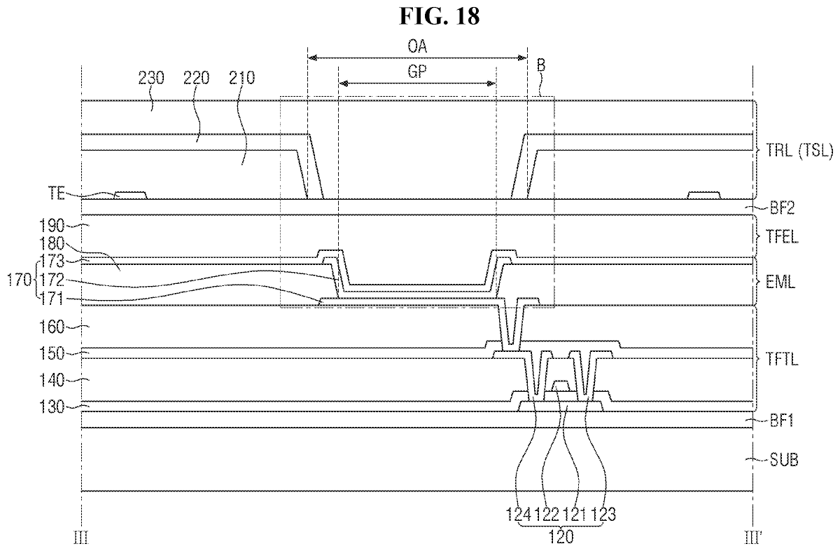

FIG. 18 is a cross-sectional view illustrating another example taken along line III-III′ of FIG. 16.

The embodiment illustrated in FIG. 18 is different from the embodiment illustrated in FIG. 17 in that a touch insulating layer TINS is omitted, and thus, a touch sensor layer TSL and a total reflection layer TRL are formed as one layer.

Referring to FIG. 18, a first total reflection layer 210 is formed on driving electrodes TE. Connection electrodes BE may be formed on the first total reflection layer 210. A second total reflection layer 220 may be formed on the connection electrodes BE. Each of the connection electrodes BE may be connected to the driving electrodes TE through contact holes penetrating the first total reflection layer 210. The driving electrodes TE disposed in the second direction (Y-axis direction) may be electrically connected by the connection electrodes BE.

In an embodiment according to FIG. 18, the driving electrodes TE, sensing electrodes RE, first driving lines TL1, second driving lines TL2, sensing lines RL, guard lines GL1 through GL5, and ground lines GRL1 through GRL3 are formed on a second buffer layer BF2, and the connection electrodes BE are formed on the first total reflection layer 210. However, embodiments of the present disclosure are not limited thereto. For example, the connection electrodes BE may be formed on the second buffer layer BF2, and the driving electrodes TE, the sensing electrodes RE, the first driving lines TL1, the second driving lines TL2, the sensing lines RL, the guard lines GL1 through GL5, and the ground lines GRL1 through GRL3 may be formed on the first total reflection layer 210.

Although the second total reflection layer 220 is disposed on first inclined surfaces SS1 and a first upper surface US1 of the first total reflection layer 210 in FIG. 18, embodiments of the present disclosure are not limited thereto. That is, the second total reflection layer 220 may also be disposed on the first total reflection layer 210 and the touch insulating layer TINS may be exposed without being covered by the first total reflection layer 210.

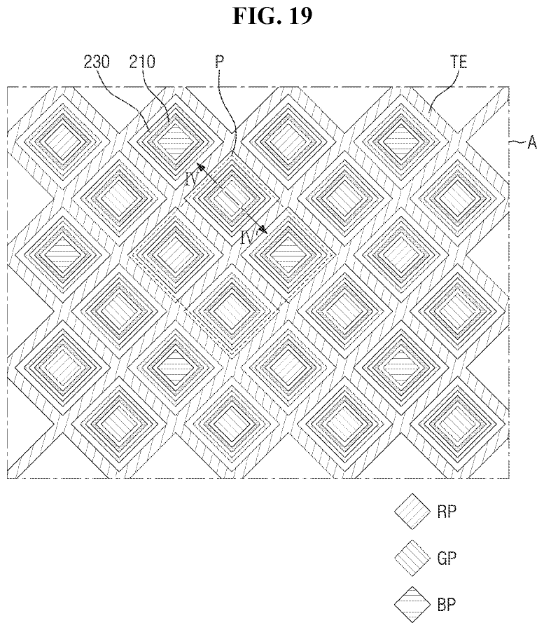

FIG. 19 is a plan view illustrating another example of the subpixels of FIG. 4 and the first touch metal layer of FIG. 5.

The embodiment illustrated in FIG. 19 is different from the embodiment illustrated in FIG. 6 in that third total reflection layers 240 surround first total reflection layers 210 when viewed in a plan view.

Referring to FIG. 19, the third total reflection layers 240 do not overlap first subpixels RP, second subpixels GP, and third subpixels BP. When viewed in a plan view, the third total reflection layers 240 may surround the subpixels RP, GP and BP, respectively. In addition, when viewed in a plan view, the third total reflection layers 240 may surround the first total reflection layers 210, respectively. In addition, a driving electrode TE may surround the third total reflection layers 240 when viewed in a plan view. The driving electrode TE does not overlap the third total reflection layers 240.

The planar shape of the third total reflection layers 240 may depend on the shape of the subpixels RP, GP and BP. For example, when the shape of the first subpixels RP, the shape of the second subpixels GP, and the shape of the third subpixels BP are the same, the shape of the third total reflection layers 240 surrounding the first subpixels RP, the shape of the third total reflection layers 240 surrounding the second subpixels GP, and the shape of the third total reflection layers 240 surrounding the third subpixels BP may be the same. Alternatively, when the shape of the first subpixels RP, the shape of the second subpixels GP, and the shape of the third subpixels BP are different from each other, the shape of the third total reflection layers 240 surrounding the first subpixels RP, the shape of the third total reflection layers 240 surrounding the second subpixels GP, and the shape of the third total reflection layers 240 surrounding the third subpixels BP may be different from each other.

When viewed in a plan view, the size of the first total reflection layers 210 may depend on the size of the subpixels RP, GP and BP. For example, when the size of the first subpixels RP, the size of the second subpixels GP, and the size of the third subpixels BP are the same in a plan view, the size of the third total reflection layers 240 surrounding the first subpixels RP, the size of the third total reflection layers 240 surrounding the second subpixels GP, and the size of the third total reflection layers 240 surrounding the third subpixels BP may be the same. Alternatively, when the size of the first subpixels RP, the size of the second subpixels GP, and the size of the third subpixels BP are different from each other in a plan view, the size of the third total reflection layers 240 surrounding the first subpixels RP, the size of the third total reflection layers 240 surrounding the second subpixels GP, and the size of the third total reflection layers 240 surrounding the third subpixels BP may be different from each other.

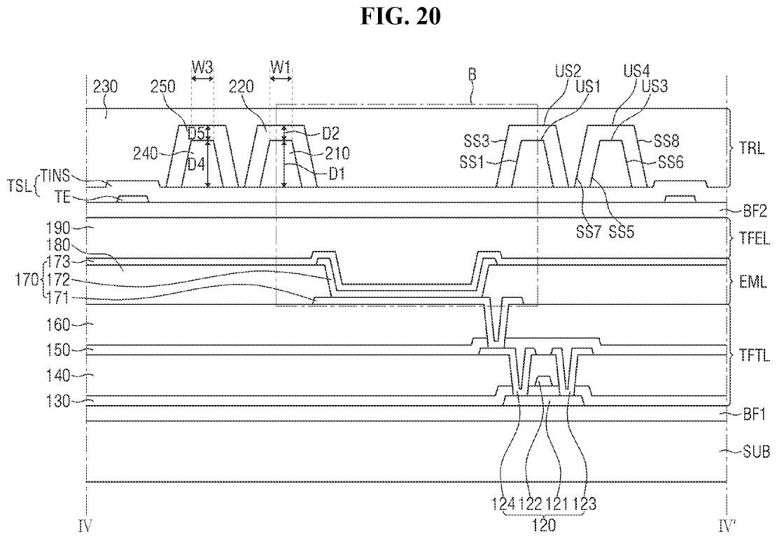

FIG. 20 is a cross-sectional view illustrating an example taken along line IV-IV′ of FIG. 19.

The embodiment illustrated in FIG. 20 is different from the embodiment illustrated in FIG. 7 in that a third total reflection layer 240 is additionally disposed.

Referring to FIG. 20, the third total reflection layer 240 may be disposed on a touch insulating layer TINS. The third total reflection layer 240 overlaps a pixel defining layer 180 and does not overlap the subpixels RP, GP and BP. The third total reflection layer 240 may include a fifth inclined surface SS5 adjacent to a second inclined surface SS2 of a first total reflection layer 210, a sixth inclined surface SS6 facing the fifth inclined surface SS5, and a third upper surface US3 connecting the fifth inclined surface SS5 and the sixth inclined surface SS6. The fifth inclined surface SS5 of the third total reflection layer 240 may be an inner surface of the third total reflection layer 240, and the sixth inclined surface SS6 may be an outer surface of the third total reflection layer 240.

A third taper angle θ3 of the fifth inclined surface SS5 of the third total reflection layer 240 may be 90 degrees or less. Therefore, the fifth inclined surface SS5 of the third total reflection layer 240 may be regularly tapered. The third taper angle θ3 is an inclination angle of the fifth inclined surface SS5 and indicates an angle formed by the touch insulating layer TINS and the fifth inclined surface SS5 of the third total reflection layer 240.

The third total reflection layer 240 may be made of an organic layer or may be made of an organic layer including inorganic particles. The organic layer may be, but is not limited to, acryl resin, epoxy resin, phenolic resin, polyamide resin, or polyimide resin. The inorganic particles may be, but are not limited to, metal particles.

The greater the thickness D4 of the third total reflection layer 240, the higher the proportion of light totally reflected from the fifth inclined surface SS5 of the third total reflection layer 240 to travel in the upward direction among light of the subpixels RP, GP and BP. Therefore, to increase the light output efficiency of the subpixels RP, GP and BP, the thickness D4 of the third total reflection layer 240 may be 1.5 um or more, preferably, about 3 um. The thickness D4 of the third total reflection layer 240 may be substantially equal to a thickness D1 of the first total reflection layer 210. In addition, a width W3 of the third total reflection layer 240 may be substantially equal to a width W1 of the first total reflection layer 210. However, embodiments of the present disclosure are not limited thereto.

A fourth total reflection layer 250 may be disposed on the third total reflection layer 240. The fourth total reflection layer 250 overlaps the pixel defining layer 180 and does not overlap the subpixels RP. GP and BP. The fourth total reflection layer 250 may include a seventh inclined surface SS7 disposed on the fifth inclined surface SS5, an eighth inclined surface SS8 disposed on the sixth inclined surface SS6, and a fourth upper surface US4 disposed on the third upper surface US3. The fourth upper surface US4 may connect the seventh inclined surface SS7 and the eighth inclined surface SS8. The third inclined surface SS3 of the fourth total reflection layer 250 may be an inner surface of the second total reflection layer 220, and the fourth inclined surface SS4 may be an outer surface.

A fourth taper angle θ4 of the seventh inclined surface SS7 of the fourth total reflection layer 250 may be 90 degrees or less. Therefore, the seventh inclined surface SS7 of the fourth total reflection layer 250 may be regularly tapered. The fourth taper angle θ4 is an inclination angle of the seventh inclined surface SS7 and indicates an angle formed by the touch insulating layer TINS and the seventh inclined surface SS7 of the fourth total reflection layer 250.

The fourth total reflection layer 250 may be made of an inorganic layer, an organic layer, or an organic layer including inorganic particles. The inorganic layer may be, but is not limited to, a silicon nitride layer, a silicon oxynitride layer, a silicon oxide layer, a titanium oxide layer, or an aluminum oxide layer. The organic layer may be, but is not limited to, acryl resin, epoxy resin, phenolic resin, polyamide resin, or polyimide resin. The inorganic particles may be, but are not limited to, metal particles.

A refractive index of the fourth total reflection layer 250 may be greater than a refractive index of the third total reflection layer 240 so that the light of the subpixels RP, GP and BP can be totally reflected from the fifth inclined surface SS5 of the third total reflection layer 240 to travel in the upward direction.

When a thickness D5 of the fourth total reflection layer 250 is equal to the thickness D4 of the third total reflection layer 240 or greater than the thickness D4 of the third total reflection layer 240, the proportion of light refracted from the seventh inclined surface SS7 of the fourth total reflection layer 250 and then totally reflected from the fifth inclined surface SS5 of the third total reflection layer 240 to travel in the upward direction (Z-axis direction) among the light of the subpixels RP, GP and BP may decrease. Therefore, the thickness D5 of the fourth total reflection layer 250 may be smaller than the thickness D4 of the third total reflection layer 240. The thickness D5 of the fourth total reflection layer 250 may be substantially equal to a thickness D2 of a second total reflection layer 220.

Although the fourth total reflection layer 250 is disposed on the fifth inclined surface SS5, the sixth inclined surface SS6, and the third upper surface US3 of the third total reflection layer 240 in FIG. 20, embodiments of the present disclosure are not limited thereto. The fourth total reflection layer 250 may also be disposed only on the fifth inclined surface SS5 and the sixth inclined surface SS6 of the third total reflection layer 240.

The fourth total reflection layer 250 may be formed to cover the touch insulating layer TINS not covered by the first total reflection layer 210 and the third total reflection layer 240 as illustrated in FIG. 8. In this case, since the second total reflection layer 220 and the fourth total reflection layer 250 can be formed as one layer without a separate mask process, the manufacturing cost can be reduced.

A high refractive planarization layer 230 may be formed on the touch insulating layer TINS, the second total reflection layer 220, and the fourth total reflection layer 250, as illustrated in FIG. 20. Alternatively, when the second total reflection layer 220 and the fourth total reflection layer 250 are formed as one layer without a separate mask process, the high refractive planarization layer 230 may be formed on the second total reflection layer 220 and the fourth total reflection layer 250. The high refractive planarization layer 230 serves to planarize steps formed by the first total reflection layer 210, the second total reflection layer 220, the third total reflection layer 240, and the fourth total reflection layer 250. To this end, a thickness D3 of the high refractive planarization layer 230 may be greater than the thickness D4 of the third total reflection layer 240.

A refractive index of the high refractive planarization layer 230 may be greater than a refractive index of the second total reflection layer 220 and the refractive index of the fourth total reflection layer 250 so that the light of the subpixels RP, GP and BP can be totally reflected from the second inclined surface SS2 of the second total reflection layer 220 to travel in the upward direction (Z-axis direction).

According to the embodiment illustrated in FIG. 20, light travelling in the lateral direction rather than the upward direction among the light of the subpixels RP, GP and BP may be, as compared with the embodiment illustrated in FIG. 7, additionally totally reflected from the seventh inclined surface SS7 of the fourth total reflection layer 250, may be totally reflected from the fifth inclined surface SS5 of the third total reflection layer 240, or may be refracted from the seventh inclined surface SS7 of the fourth total reflection layer 250 and then totally reflected from the fifth inclined surface SS5 of the third total reflection layer 240 to travel in the upward direction. Therefore, it is possible to further increase the light output efficiency of the subpixels RP, GP and BP, thereby further increasing the life of organic light emitting elements and further reducing the power consumption of an organic light emitting display.

In addition, among the light of the subpixels RP, GP and BR light totally reflected by the fifth inclined surface SS5 of the third total reflection layer 240, light totally reflected by the seventh inclined surface SS7 of the fourth total reflection layer 250, and light refracted by the seventh inclined surface SS7 of the fourth total reflection layer 250 and then totally reflected by the fifth inclined surface SS5 of the third total reflection layer 240 are totally reflected by substantially the same principle as the first light L1, the second light L2, and the third light L3 described in conjunction with FIGS. 9 through 15, and thus, a detailed description thereof is omitted.

Although the second total reflection layer 220 is disposed only on the first total reflection layer 210, and the fourth total reflection layer 250 is disposed only on the third total reflection layer 240 in FIG. 20, embodiments of the present disclosure are not limited thereto. That is, the second total reflection layer 220 and the fourth total reflection layer 250 may also be formed as one layer and disposed on the first total reflection layer 210, the third total reflection layer 240, and the touch insulating layer TINS exposed without being covered by the first total reflection layer 210 and the third total reflection layer 240. In this case, the second total reflection layer 220 and the fourth total reflection layer 250 formed as one layer may cover a driving electrode TE.

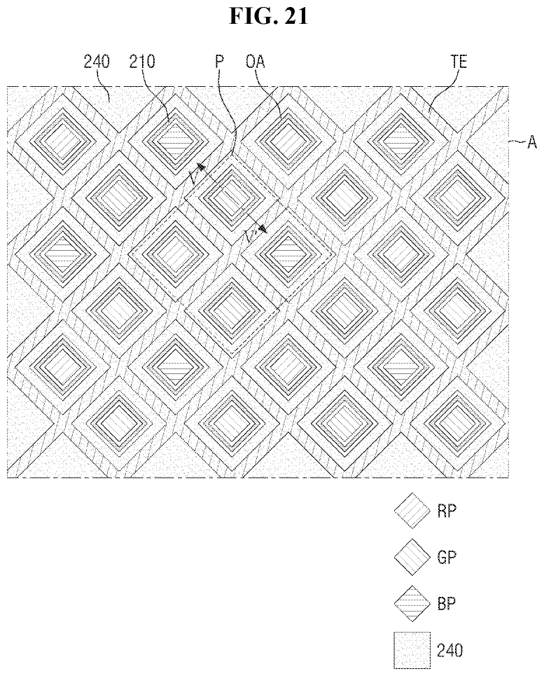

FIG. 21 is a plan view illustrating another example of the subpixels of FIG. 4 and the first touch metal layer of FIG. 5.

The embodiment illustrated in FIG. 21 is different from the embodiment illustrated in FIG. 6 in that a third total reflection layer 240 overlaps a driving electrode TE.

Referring to FIG. 21, the third total reflection layer 240 does not overlap first subpixels RP, second subpixels GP, and third subpixels BP when viewed in a plan view. The third total reflection layer 240 may include opening areas OA exposing the subpixels RP, GP and BP and first total reflection layers 210 when viewed in a plan view.

The planar shape of the opening areas OA may depend on the shape of the subpixels RP, GP and BP. In addition, when viewed in a plan view, the size of the opening areas OA may depend on the size of the subpixels RP, GP and BP.

The third total reflection layer 240 may overlap the driving electrode TE. Since a sensing electrode RE may be formed substantially the same as the driving electrode TE, the third total reflection layer 240 may overlap the sensing electrode RE. In addition, since a connection electrode BE overlaps the driving electrode TE and the sensing electrode RE as illustrated in FIG. 5, the first total reflection layer 210 may overlap the connection electrode BE.

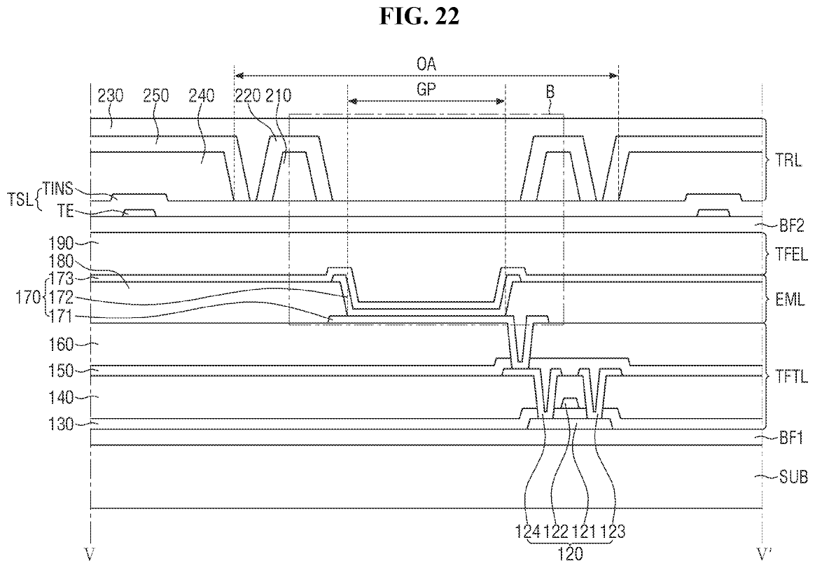

FIG. 22 is a cross-sectional view illustrating an example taken along line V-V′ of FIG. 21.

The embodiment illustrated in FIG. 22 is different from the embodiment illustrated in FIG. 20 in that the third total reflection layer 240 includes fifth inclined surfaces SS5 defining the opening area OA exposing each of the subpixels RP, GP and BP and that the third total reflection layer 240 is formed to cover the driving electrode TE.

Referring to FIG. 22, the third total reflection layer 240 may be formed to cover the driving electrode TE and a touch insulating layer TINS, except for the opening area OA exposing each of the subpixels RP, GP and BP as illustrated in FIG. 22.

Although a second total reflection layer 220 is disposed only on a first total reflection layer 210, and a fourth total reflection layer 250 is disposed only on the third total reflection layer 240 in FIG. 22, embodiments of the present disclosure are not limited thereto. That is, the second total reflection layer 220 and the fourth total reflection layer 250 may also be formed as one layer and disposed on the first total reflection layer 210, the third total reflection layer 240, and the touch insulating layer TINS exposed without being covered by the first total reflection layer 210 and the third total reflection layer 240.

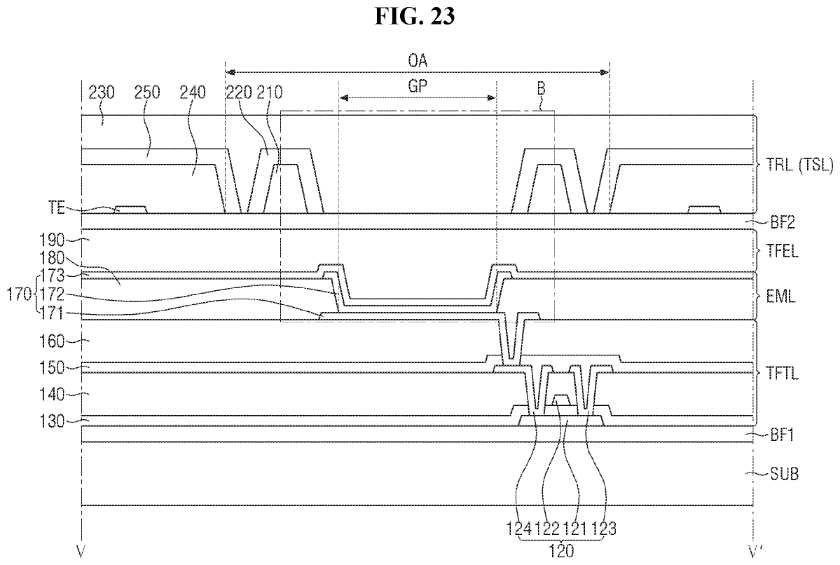

FIG. 23 is a cross-sectional view illustrating another example taken along line V-V′ of FIG. 21.

The embodiment illustrated in FIG. 23 is different from the embodiment illustrated in FIG. 22 in that a touch insulating layer TINS is omitted, and thus, a touch sensor layer TSL and a total reflection layer TRL are formed as one layer.

Referring to FIG. 23, a third total reflection layer 240 is formed on driving electrodes TE. Connection electrodes BE may be formed on the third total reflection layer 240. A fourth total reflection layer 250 may be formed on the connection electrodes BE. Each of the connection electrodes BE may be connected to the driving electrodes TE through contact holes penetrating the third total reflection layer 240. The driving electrodes TE disposed in the second direction (Y-axis direction) may be connected by the connection electrodes BE.

In an embodiment according to FIG. 23, the driving electrodes TE, sensing electrodes RE, first driving lines TL1, second driving lines TL2, sensing lines RL, guard lines GL1 through GL5, and ground lines GRL1 through GRL3 are formed on a second buffer layer BF2, and the connection electrodes BE are formed on the third total reflection layer 240. However, embodiments of the present disclosure are not limited thereto. For example, the connection electrodes BE may be formed on the second buffer layer BF2, and the driving electrodes TE, the sensing electrodes RE, the first driving lines TL1, the second driving lines TL2, the sensing lines RL, the guard lines GL1 through GL5, and the ground lines GRL1 through GRL3 may be formed on the third total reflection layer 240.

Although a second total reflection layer 220 is disposed only on a first total reflection layer 210, and the fourth total reflection layer 250 is disposed only on the third total reflection layer 240 in FIG. 23, embodiments of the present disclosure are not limited thereto. That is, the second total reflection layer 220 and the fourth total reflection layer 250 may also be formed as one layer and disposed on the first total reflection layer 210, the third total reflection layer 240, and the touch insulating layer TINS exposed without being covered by the first total reflection layer 210 and the third total reflection layer 240.

Although preferred embodiments of the present invention have been described for illustrative purposes, those skilled in the art will appreciate that various modifications, additions and substitutions are possible, without departing from the scope and spirit of the invention as disclosed in the accompanying claims.

1. A display device comprising:
a subpixel comprising a first electrode, a light emitting layer, and a second electrode;
a pixel defining layer defining the subpixel;
a first total reflection layer overlapping the pixel defining layer;
a second total reflection layer disposed on the first total reflection layer; and
a planarization layer disposed on the second total reflection layer,
wherein a refractive index of the planarization layer is greater than a refractive index of the second total reflection layer, and the refractive index of the second total reflection layer is greater than a refractive index of the first total reflection layer.

2. The display device of claim 1, wherein a maximum thickness of the planarization layer is greater than a maximum thickness of the first total reflection layer, and the maximum thickness of the first total reflection layer is greater than a maximum thickness of the second total reflection layer.

3. The display device of claim 1, wherein the first total reflection layer does not overlap the subpixel.

4. The display device of claim 1, further comprising:
an encapsulation layer disposed on the second electrode of the subpixel and the pixel defining layer,
wherein the first total reflection layer is disposed on the encapsulation layer, and the second total reflection layer is disposed on a portion of the encapsulation layer that is not covered by the first total reflection layer.

5. The display device of claim 4, further comprising:
a buffer layer disposed between the encapsulation layer and the first total reflection layer.

6. The display device of claim 1, wherein the first total reflection layer surrounds the subpixel in a plan view.

7. The display device of claim 1, further comprising:
a touch electrode overlapping the pixel defining layer.

8. The display device of claim 7, wherein the touch electrode does not overlap the first total reflection layer.

9. The display device of claim 8, wherein the second total reflection layer covers the touch electrode.

10. The display device of claim 7, wherein the first total reflection layer covers the touch electrode.

11. The display device of claim 10, wherein the first total reflection layer comprises an opening area exposing the subpixel in a plan view.

12. The display device of claim 7, further comprising:
a touch insulating layer covering the touch electrode,
wherein the first total reflection layer is disposed on the touch insulating layer.

13. The display device of claim 1, further comprising:
a third total reflection layer overlapping the pixel defining layer,
wherein the first total reflection layer surrounds the subpixel in a plan view, and the third total reflection layer surrounds the first total reflection layer in the plan view.

14. The display device of claim 13, further comprising:
a fourth total reflection layer disposed on the third total reflection layer,
wherein a refractive index of the fourth total reflection layer is greater than a refractive index of the third total reflection layer.

15. The display device of claim 13, further comprising:
an encapsulation layer disposed on the second electrode of the subpixel and the pixel defining layer,
wherein the first total reflection layer and the third total reflection layer are disposed on the encapsulation layer, and the second total reflection layer is disposed on the third total reflection layer and a portion of the encapsulation layer that is not covered by the first total reflection layer and the third total reflection layer.

16. The display device of claim 13, further comprising:
a touch electrode overlapping the pixel defining layer.

17. The display device of claim 16, wherein the touch electrode does not overlap the first total reflection layer and the third total reflection layer.

18. The display device of claim 17, wherein the second total reflection layer covers the touch electrode.

19. The display device of claim 16, wherein the third total reflection layer covers the touch electrode.

20. The display device of claim 16, further comprising:
a touch insulating layer covering the touch electrode,
wherein the first total reflection layer and the third total reflection layer are disposed on the touch insulating layer.

21. The display device of claim 1,
wherein the first total reflection layer comprises a first inclined surface adjacent to the subpixel, and the second total reflection layer comprises a second inclined surface disposed on the first inclined surface,
wherein an inclination angle of the first inclined surface is defined as a first taper angle, an inclination angle of the second inclined surface is defined as a second taper angle, and each of the first taper angle and the second taper angle increases as each of an output angle of light that is totally reflected by the first total reflection layer and an output angle of light that is totally reflected by the second total reflection layer increases.

22. The display device of claim 1,
wherein the first total reflection layer comprises a first inclined surface adjacent to the subpixel, and the second total reflection layer comprises a second inclined surface disposed on the first inclined surface,
wherein an inclination angle of the first inclined surface is defined as a first taper angle, an inclination angle of the second inclined surface is defined as a second taper angle, and each of the first taper angle and the second taper angle decreases as an output angle of light that is refracted by the second total reflection layer and then totally reflected by the first total reflection layer increases.
